(19) United States
(12) Patent Application Publication
(10) Pub. No.: US 2026/0033293 A1
(43) Pub. Date: Jan. 29, 2026

(54) SUBSTRATE TREATMENT METHOD AND SUBSTRATE TREATMENT SYSTEM

(71) Applicant: Samsung Electronics Co., Ltd., Suwon-si (KR)

(72) Inventors: Inbeom YIM, Suwon-si (KR); Jeongjin LEE, Suwon-si (KR); Eunho LEE, Suwon si (KR); Seungyoon LEE, Suwon-si (KR); Chan HWANG, Suwon-si (KR)

(21) Appl. No.: 19/092,126

(22) Filed: Mar. 27, 2025

(30) Foreign Application Priority Data
Jul. 26, 2024 (KR) 10-2024-0099371

(51) Int. Cl. H01L 21/66; H01L 23/544

(52) U.S. Cl. CPC H01L 22/12; H01L 23/544; H01L 2223/54426

(57) ABSTRACT

A substrate treatment method includes determining a first model of an upper substrate and a lower substrate based on alignment error data taken by measuring positions of a plurality of alignment marks of each of the upper substrate and the lower substrate, determining a second model of the upper substrate and the lower substrate based on first sampling alignment error data regarding at least one alignment mark from the alignment error data, determining a third model of the upper substrate and the lower substrate based on second sampling alignment error data taken by measuring positions of the at least one alignment mark, determining a fourth model by correcting the third model based on a difference between the second model and the first model, and aligning a position of a substrate selected between the upper substrate and the lower substrate according to the fourth model.

### CROSS-REFERENCE TO RELATED APPLICATION

This application claims the benefit of Korean Patent Application No. 10-2024-0099371, filed on Jul. 26, 2024, in the Korean Intellectual Property Office, the disclosure of which is incorporated herein by reference.

### BACKGROUND

### 1. Field of the Invention

Example embodiments relate to a substrate treatment method and a substrate treatment system.

### 2. Description of the Related Art

A substrate treatment system can manufacture semiconductor devices by treating substrates such as wafers and printed circuit substrates. As semiconductor devices have become increasingly miniaturized and improved in performance, technologies for more precise alignment of substrates have been desirable. Since the cost of replacing equipment within a substrate treatment system is very high, the importance of technologies that enable precise alignment using existing equipment is increasing.

### SUMMARY

An aspect provides a substrate treatment method and a substrate treatment system by which substrates are accurately aligned.

The technical tasks to be achieved by the present example embodiments are not limited to the technical tasks described above, and other technical tasks may be inferred from the following example embodiments.

According to an aspect, a substrate treatment method includes determining a first model of an upper substrate and a lower substrate based on alignment error data for taken by measuring positions of a plurality of alignment marks of each of the upper substrate and the lower substrate; determining a second model of the upper substrate and the lower substrate based on first sampling alignment error data for regarding at least one alignment mark of the plurality of alignment marks, the first sampling alignment error data being selected from the alignment error data; determining a third model of the upper substrate and the lower substrate based on second sampling alignment error data for taken by measuring positions of the at least one alignment mark of each of the upper substrate and the lower substrate; determining a fourth model by correcting the third model based on a difference between the second model and the first model; and aligning a position of a substrate selected between the upper substrate and the lower substrate according to the fourth model.

According to another aspect, a substrate treatment method includes obtaining a first mean value for an alignment error of each of a plurality of first alignment marks measured during a first exposure process for performed on an upper substrate comprising the plurality of first alignment marks; obtaining a second mean value for an alignment error of at least one first alignment mark among the plurality of first alignment marks; obtaining a third mean value for an alignment error of each of a plurality of second alignment marks measured during a second exposure process for performed on a lower substrate comprising the plurality of second alignment marks; obtaining a fourth mean value for an alignment error of at least one second alignment mark among the plurality of second alignment marks; obtaining a fifth mean value for an alignment error between the at least one first alignment mark and the at least one second alignment mark measured during a bonding process of the upper substrate and to the lower substrate; obtaining an offset by correcting the fifth mean value based on a first difference value of between the second mean value and the first mean value, and a second difference value of between the fourth mean value and the third mean value; and aligning a position of a substrate selected between the upper substrate and the lower substrate according to the offset.

According to another aspect, a substrate treatment system includes an electronic apparatus including a processor configured to: determine a first model of an upper substrate and a lower substrate based on alignment error data regarding a plurality of alignment marks of each of the upper substrate and the lower substrate; and determine a second model of the upper substrate and the lower substrate based on first sampling alignment error data regarding at least one alignment mark from the alignment error data; and a bonding apparatus configured to: determine a third model of the upper substrate and the lower substrate based on second sampling alignment error data taken by measuring positions of the at least one alignment mark; determine a fourth model by correcting the third model based on a difference between the second model and the first model received from the electronic apparatus; and align a position of a substrate selected between the upper substrate and the lower substrate according to the fourth model.

Additional aspects of example embodiments will be set forth in part in the description which follows and, in part, will be apparent from the description, or may be learned by practice of the disclosure.

According to example embodiments, it is possible to provide a substrate treatment method and a substrate treatment system by which substrates are accurately aligned. According to example embodiments, it is possible to provide an accurate model for the substrate alignment even in the case where the amount of measurement data for the substrate is small.

Effects of the present disclosure are not limited to those described above, and other effects may be made apparent to those skilled in the art from the following description.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1A and FIG. 1B are drawings for explaining a substrate treatment system according to an example embodiment;

FIG. 2 is a flowchart for explaining a substrate treatment method according to an example embodiment;

FIG. 3A is a diagram for explaining a model obtaining process according to an example embodiment;

FIG. 3B is a diagram for explaining the process for obtaining a specific model according to an example embodiment;

FIG. 4 is a drawing for explaining a substrate according to an example embodiment;

FIG. 5 is a diagram for explaining alignment error data according to an example embodiment;

FIG. 6 is a drawing for explaining a cross-section of a substrate according to an example embodiment;

FIG. 7 is a drawing for explaining alignment error of a substrate according to an example embodiment;

FIG. 8 is a drawing for explaining alignment error of a flipped substrate according to an example embodiment;

FIG. 9 is a drawing to explain bonding an upper substrate to a lower substrate according to an example embodiment;

FIGS. 10 to 12 are drawings for explaining the alignment of the upper substrate and the lower substrate according to an example embodiment;

FIGS. 13 to 15 are drawings for explaining the alignment of the upper substrate and the lower substrate according to an example embodiment;

FIG. 16 is a flowchart for explaining a substrate treatment method according to an example embodiment;

FIG. 17 is a drawing for explaining a process of obtaining offset according to an example embodiment;

FIG. 18 is a diagram for explaining the process for obtaining a delta value according to an example embodiment;

FIG. 19 is a drawing for explaining a bonding apparatus according to an example embodiment;

FIG. 20 is a drawing for explaining an exposure apparatus according to an example embodiment; and

FIG. 21 is a drawing for explaining an auto process control (APC) according to an example embodiment.

### DETAILED DESCRIPTION

Terms used in the example embodiments are selected from currently widely used general terms when possible while considering the functions in the present disclosure. However, the terms may vary depending on the intention or precedent of a person skilled in the art, the emergence of new technology, and the like. Further, in certain cases, there are also terms arbitrarily selected by the applicant, and in the cases, the meaning will be described in detail in the corresponding descriptions. Therefore, the terms used in the present disclosure should be defined based on the meaning of the terms and the contents of the present disclosure, rather than the simple names of the terms.

Throughout the specification, when a part is described as “comprising” or “including” a component, it does not exclude another component but may further include another component unless otherwise stated. Furthermore, terms such as “ . . . unit,” “ . . . group,” and “ . . . module” described in the specification mean a unit that processes at least one function or operation, which may be implemented as hardware, software, or a combination thereof.

Hereinafter, example embodiments of the present disclosure will be described in detail with reference to the accompanying drawings so that those of ordinary skill in the art to which the present disclosure pertains may easily implement them. However, the present disclosure may be implemented in multiple different forms and is not limited to the example embodiments described herein.

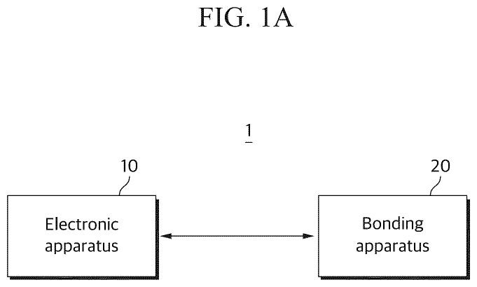

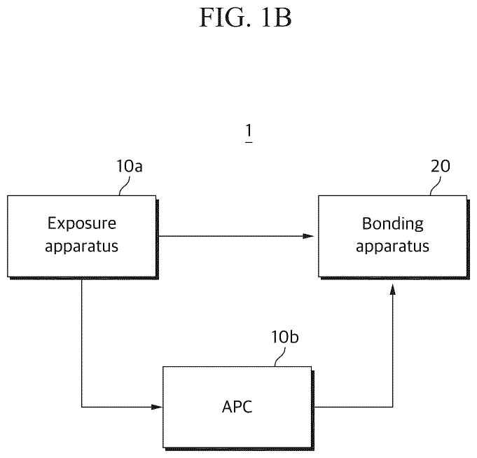

FIG. 1A and FIG. 1B are drawings for explaining a substrate treatment system according to an example embodiment.

Referring to FIG. 1A, a substrate treatment system 1 may include an electronic apparatus 10 and a bonding apparatus 20. Referring to FIG. 1A and FIG. 1B, the electronic apparatus 10 may include at least one of an exposure apparatus 10a and an auto process control (APC).

The substrate treatment system 1 may manufacture a semiconductor device using a substrate. In an example embodiment, the substrate may be a material used in the manufacture of a semiconductor device. For example, the substrate may be a base substrate of a wafer, such as a crystalline semiconductor substrate and/or support substrate, and include at least one of a silicon (Si) wafer, a gallium arsenide (GaAs) wafer, a sapphire (Al₂O₃) wafer, a germanium (Ge) wafer, a gallium nitride (GaN) wafer, a silicon carbide (SiC) wafer, a glass substrate, a ceramic substrate, and an interposer. For example, the substrate may be a thin film whose height-wise length is very small compared to its horizontal length. In an example embodiment, the semiconductor device is a device manufactured using a substrate and may include semiconductor elements. For example, the semiconductor device may be a semiconductor chip in which an integrated circuit is formed, such as one of various types such as central processing unit, graphic processing unit, application processing unit, neural network processing unit, digital signal processor, dynamic random access memory (DRAM), high bandwidth memory (HBM), static RAM (SRAM), flash memory, solid state drive (SSD), main board, an image sensor, various semiconductor sensors, micro-electro-mechanical systems (MEMS), light emitting diode (LED), laser diode, amplifier, filter, modulator, photodiode, solar power generation device, communication circuit, and integrated circuit. Meanwhile, the example embodiments described above for substrates and semiconductor devices are only examples, and the substrate and the semiconductor device may be implemented in various modified forms.

The bonding apparatus 20 may bond one substrate to another substrate. In an example embodiment, the bonding apparatus 20 may align the positions of the substrates so that one substrate faces the other substrate. For example, one substrate may be placed on top of the other substrate in order for the two substrates to face each other. In the bonding process, the substrate placed in the upper portion may be referred to as the upper substrate, and the substrate placed in the lower portion may be referred to as the lower substrate. For clarity of explanation, in the following, one substrate and the other substrate will be specifically described using the terms upper substrate and lower substrate. The upper portion and the lower portion may indicate relative positions in the height direction (for example, in the Z-axis direction). The bonding apparatus 20 may bond the upper substrate and the lower substrate to each other while the upper substrate and the lower substrate are in contact with each other. The bonding may indicate that the upper substrate and the lower substrate are physically joined to each other. At least one of heat, ultrasound, laser and pressure may be used for bonding.

In an example embodiment, the bonding apparatus 20 may measure the positional difference between the upper substrate and the lower substrate for bonding, and align the positions of the upper substrate and the lower substrate.

In an example embodiment, each of the upper substrate and the lower substrate may include an alignment mark. The alignment mark may be used as a reference point for aligning the substrates. The alignment mark may have a preset shape for identification by the bonding apparatus 20. For example, the preset shape may have one of various shapes, such as a polygon (for example, a triangle and/or a square), a circle, an ellipse, a ring and so on, or may have a shape that is a combination of two or more of these. The alignment mark may be formed on the surface (or interior) of the upper substrate and/or the lower substrate.

In an example embodiment, each of the upper substrate and the lower substrate may include a plurality of alignment marks. The plurality of alignment marks may be spaced apart from each other in a specific direction. For example, the plurality of alignment marks may be spaced apart in at least one direction between a first horizontal direction (for example, X-axis direction) and a second horizontal direction (for example, Y-axis direction). Each alignment mark may have relative coordinates within the upper substrate or the lower substrate.

The bonding apparatus 20 may identify alignment marks included in each of the upper substrate and the lower substrate, and obtain alignment error data for corresponding alignment marks. Alignment marks with the same relative coordinates in the upper substrate and the lower substrate may correspond to each other. Relative coordinates represent the arrangement relationship of alignment marks, and represent relative positions within a substrate. For example, the relative coordinate of (0, 0) may represent an alignment mark located in the center area of the upper substrate or the lower substrate.

The alignment error data may include coordinates of alignment marks and alignment errors. The coordinates of the alignment mark may indicate the measurement position of the alignment mark. The alignment error may indicate a positional difference between corresponding alignment marks on the upper substrate and alignment marks on the lower substrate. A larger alignment error value may indicate larger positional difference. In other words, the larger the alignment error value, the farther the alignment mark of the upper substrate is from the alignment mark of the lower substrate. Meanwhile, alignment error may exist in each alignment direction of the alignment mark. For example, when the alignment direction includes the first horizontal direction, alignment error data may include alignment errors in the first horizontal direction. When the alignment direction includes the first horizontal direction and the second horizontal direction, the alignment error data may include alignment errors in the first horizontal direction and alignment errors in the second horizontal direction.

The bonding apparatus 20 may align the upper substrate and the lower substrate so that alignment error with respect to corresponding alignment marks is minimized. The smaller the alignment error value, the closer the alignment mark of the upper substrate is to the alignment mark of the lower substrate. In other words, as the alignment error decreases, the degree to which alignment marks overlap may increase, and the upper substrate and the lower substrate may be aligned with each other in more precise positions.

In an example embodiment, the bonding apparatus 20 may perform alignment using corresponding alignment marks of some of the entire alignment marks of each of the upper substrate and the lower substrate. In other words, the bonding apparatus 20 may select only some alignment marks having the same relative coordinates on each of the upper substrate and the lower substrate and use the alignment marks for alignment. Here, the case where alignment error data for a small number of alignment marks is used may be referred to as subsampling or just sampling. The alignment error data in this case may be referred to as sampling alignment error data. Meanwhile, the case where the entire alignment marks (e.g., all of the alignment marks) or more than the number of alignment marks for the subsampling are used may be referred to as full sampling. In the case of subsampling, compared to full sampling, the number of data to be processed is reduced, which may improve the process speed. Further, in the case of subsampling, the hardware and/or software required for alignment may be relatively simplified, which may reduce costs. However, in the case of subsampling, offset, rotations, mechanical deformations and so on that occur in the substrate are not as accurately detected, and thus the accuracy of the alignment may be reduced. According to example embodiments of the present disclosure, provided is the substrate treatment system 1 by which alignment accuracy is improved.

In an example embodiment, the electronic apparatus 10 may determine the first model of the upper substrate and the lower substrate by using alignment error data for multiple alignment marks of each of the upper substrate and lower substrate. The alignment error data for the multiple alignment marks may be measured during the process prior to the bonding process of the bonding apparatus 20. Here, the process may refer to a unit process such as heat treatment process, exposure process, etching process, deposition process, bonding process, and cutting process during the process of manufacturing a semiconductor device. For example, the alignment error data for the multiple alignment marks may be measured during the exposure process, which requires high-precision alignment. The first model may be a full-sampling model to align the substrates. The first model may be used for alignment in the process prior to the bonding process (for example, the exposure process). The first model may include an alignment error component corresponding to at least one of offset, rotation and transformation.

The electronic apparatus 10 may determine the second model of the upper substrate and the lower substrate by using the first sampling alignment error data for at least one alignment mark from the alignment error data. Here, the first sampling alignment error data for at least one alignment mark may be included in the alignment error data for multiple alignment marks. For example, first sampling alignment error data is not newly measured, and may be alignment error data for at least one alignment mark from the alignment error data for multiple alignment marks already measured, e.g., in the previous process. In other words, the electronic apparatus 10 may obtain alignment error data for at least one alignment mark from alignment error data for multiple alignment marks that is already measured as first sampling alignment error data, and determine the second model of the upper substrate and lower substrate using the alignment error data. The second model may be a subsampling model to align the substrates.

In an example embodiment, the electronic apparatus 10 may include the exposure apparatus 10a. The exposure apparatus 10a may measure alignment error data for multiple alignment marks. In an example embodiment, the exposure apparatus 10a may determine the first model using alignment error data. The exposure apparatus 10a may form a micropattern on a substrate by aligning the substrate according to the first model and exposing the substrate.

In an example embodiment, the exposure apparatus 10a may determine the second model using first sampling alignment error data. In an example embodiment, the exposure apparatus 10a may transmit the first model and the second model to the bonding apparatus 20 through an APC 10b. In another example embodiment, the exposure apparatus 10a may transmit the first model and the second model to the bonding apparatus 20.

In an example embodiment, the electronic apparatus 10 may include the APC 10b. The APC 10b may collect and analyze data (for example, temperature, pressure, alignment error, and so on) from manufacturing equipment of each process. The APC 10b may adjust process variables (for example, temperature, exposure time, substrate position and so on) based on the results of data analysis.

In an example embodiment, the APC 10b may receive alignment error data for multiple alignment marks from the exposure apparatus 10a. In other words, the exposure apparatus 10a may transmit the alignment error data for the multiple alignment marks to the APC 10b. In this case, the APC 10b may determine the first model of the upper substrate and the lower substrate using the alignment error data for the multiple alignment marks. The APC 10b may determine a second model of the upper substrate and the lower substrate using the first sampling alignment error data for at least one alignment mark in the alignment error data. In an example embodiment, the APC 10b may transmit the first model and the second model to the bonding apparatus 20.

The bonding apparatus 20 may determine the third model of the upper substrate and the lower substrate by using second sampling alignment error data for at least one alignment mark of each of the upper substrate and the lower substrate. The second sampling alignment error data and the first sampling alignment error data may be measured targeting the same alignment mark. In other words, the second sampling alignment error data and the first sampling alignment error data are measured during different processes for alignment marks having the same relative coordinates as each other. The third model may be a subsampling model for aligning one substrate selected between the upper substrate and the lower substrate.

The bonding apparatus 20 may determine the fourth model by correcting the third model using the difference between the second model and the first model. The bonding apparatus 20 may align a position of a substrate selected from between the upper substrate and the lower substrate according to the fourth model. For example, the bonding apparatus 20 may align either one of the upper substrate and the lower substrate according to the fourth model.

In an example embodiment, each of the first model to the fourth model may be a linear model or a polynomial model for aligning the substrates. Each of the first model to the fourth model may include at least one alignment error component. The alignment error component may be one of an offset component, a rotation component and a scale component. The offset component may indicate that the alignment is off in the same direction (e.g., by being translated in a horizontal direction). The rotation component may represent a state in which the alignment is off by being rotated around a central axis. The scale component may indicate how much the alignment is misaligned depending on the position of the alignment mark. Each of the first model to the fourth model may include at least one coefficient. Here, the coefficient may be a value for the alignment error component. In other words, each alignment error component may have a coefficient of a specific value.

For example, the bonding apparatus 20 may receive the second model and the first model from the electronic apparatus 10. The bonding apparatus 20 may calculate the first difference value by subtracting the coefficient of the first model from the coefficient of the second model, calculate the second difference value by subtracting the first difference value from the coefficient of the third model, and determine a fourth model with the second difference value as a coefficient. Here, the fourth model may be the final model for aligning the substrates during the bonding process.

According to example embodiments, without collecting alignment error data for the entire plurality of alignment marks, the bonding apparatus 20 may determine a fourth model with improved alignment accuracy by correcting the third model generated according to the subsampling method by using the first model generated according to the full-sampling method already obtained from another device and the second model generated according to the subsampling method.

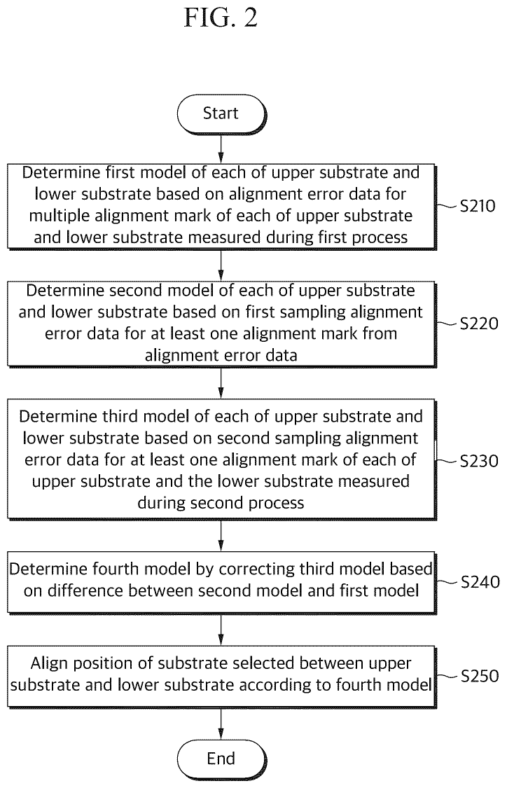

FIG. 2 is a flowchart for explaining a substrate treatment method according to an example embodiment.

Referring to FIG. 2, the substrate treatment method may include operation S210 in which a first model of the upper substrate and the lower substrate is determined based on alignment error data for multiple alignment marks of each of the upper substrate and the lower substrate, operation S220 in which a second model of the upper substrate and lower substrate is determined based on the first sampling alignment error data for at least one alignment mark from the alignment error data, operation S230 in which a third model of the upper substrate and the lower substrate is determined based on second sampling alignment error data for at least one alignment mark of each of the upper substrate and the lower substrate, operation S240 in which a fourth model is determined by correcting the third model based on the difference between the second model and the first model, and operation S250 in which a position of a substrate selected between the upper substrate and lower substrate is aligned according to the fourth model. The substrate treatment method of the present disclosure may be performed by the substrate treatment system 1 described above.

In an example embodiment, the substrate treatment method may include operation S210 in which the first model of the upper substrate and the lower substrate is determined using alignment error data for multiple alignment marks of each of the upper substrate and the lower substrate.

Specifically, in the substrate treatment method, the first model of the upper substrate is determined by using alignment error data for multiple alignment marks included in the upper substrate. In the substrate treatment method, the first model of the lower substrate is determined by using alignment error data for multiple alignment marks included in the lower substrate. Here, the upper substrate and the lower substrate may refer to different substrates. Each of the upper substrate and the lower substrate may include a plurality of alignment marks formed at positions corresponding to each other.

In an example embodiment, the first model may be determined using alignment error data measured during the first process.

The alignment error data for multiple alignment marks of the upper substrate may be measured in the first process for the upper substrate. The first model of the upper substrate may be a model for aligning the upper substrate in the first process. The alignment error data for multiple alignment marks of the lower substrate may be measured in the first process for the lower substrate. The first model of the lower substrate may be a model for aligning the lower substrate in the first process.

In an example embodiment, the upper substrate may be a substrate placed in the upper portion (e.g., of bonding apparatus 20) in the second process that is after the first process, and the lower substrate may be a substrate placed on the lower portion (e.g., of bonding apparatus 20) in the second process. For example, the first process may be the exposure process and the second process may be the bonding process. However, the above a mere example embodiment, and the first process and the second process may be different from the above described processes.

In an example embodiment, the substrate treatment method may include operation S220 in which the second model of the upper substrate and lower substrate is determined by using the first sampling alignment error data for at least one alignment mark in the alignment error data for multiple alignment marks of each of the upper substrate and the lower substrate.

Specifically, in the substrate treatment method, the second model of the upper substrate is determined by using the first sampling alignment error data for at least one alignment mark in the alignment error data for multiple alignment marks included in the upper substrate. In the substrate treatment method, the second model of the lower substrate is determined by using the first sampling alignment error data for at least one alignment mark in the alignment error data for multiple alignment marks included in the lower substrate.

The first sampling alignment error data of the upper substrate may be sampled from the alignment error data for multiple alignment marks of the upper substrate that is already measured. In other words, the first sampling alignment error data of the upper substrate may be alignment error data for at least one alignment mark sampled from among a plurality of alignment marks included in the upper substrate. The first sampling alignment error data of the lower substrate may be sampled from the alignment error data for multiple alignment marks of the lower substrate that is already measured. In other words, the first sampling alignment error data of the lower substrate may be alignment error data for at least one alignment mark sampled from among multiple alignment marks included in the lower substrate.

In an example embodiment, the substrate treatment method may include operation S230 in which the third model of the upper substrate and the lower substrate is determined using second sampling alignment error data for at least one alignment mark of each of the upper substrate and the lower substrate.

Specifically, in the substrate treatment method, a third model of the upper substrate and the lower substrate is determined by using second sampling alignment error data for at least one alignment mark of the upper substrate. In the substrate treatment method, the third model of the lower substrate is determined by using the second sampling alignment error data for at least one alignment mark of the lower substrate. For example, the second sampling alignment error data may be measured during the second process.

In an example embodiment, the first model to the third model of the present disclosure may be determined using respective alignment error data through a statistical method (for example, regression analysis). For example, the coordinates and alignment error for one alignment mark may be composed into one dataset, and the optimized coefficient of the linear model (or polynomial model) may be determined using each dataset. The first model to the third model may be linear models (or polynomial models) with coefficients optimized for each dataset.

In an example embodiment, the third model may be determined using second sampling alignment error data measured in the second process after the first process. In an example embodiment, the first process may be the exposure process and the second process may be the bonding process.

The second sampling alignment error data of the upper substrate may be measured in the second process. In an example embodiment, an alignment mark of the upper substrate measured in the second process to obtain second sampling alignment error data may be the same as the alignment mark of the upper substrate measured in the first process to obtain the first sampling alignment error data. In other words, the first sampling alignment error data and the second sampling alignment error data are for the same measurement target, and may be measured in different processes.

The second sampling alignment error data of the lower substrate may be measured in the second process. In an example embodiment, the alignment mark of the lower substrate measured in the second process to obtain the second sampling alignment error data may be the same as the alignment mark of the lower substrate measured in the first process to obtain the first sampling alignment error data. In other words, the first sampling alignment error data and the second sampling alignment error data are for the same measurement target, and may be measured in different processes.

In an example embodiment, the substrate treatment method may include operation S240 in which the fourth model is determined by correcting the third model using the difference between the second model and the first model.

Specifically, each of the first model to the fourth model may be a linear model or a polynomial model for aligning the substrates. Each of the first model to the fourth model may include at least one alignment component among an offset component, a rotation component and a scale component, and a coefficient for each alignment component. For example, in the substrate treatment method, the fourth model may be determined in which the first difference value may be calculated by subtracting the coefficient of the first model from the coefficient of the second model, the second difference value may be calculated by subtracting the first difference value from the coefficient of the third model, and the second difference value is used as a coefficient of the fourth model.

In an example embodiment, the substrate treatment method may include operation S250 in which a position of a substrate selected between the upper substrate and lower substrate is aligned according to the fourth model. The selected substrate may be either the upper substrate or the lower substrate. For example, the selected substrate may be the upper substrate, but this is a mere example embodiment, and the selected substrate may be the lower substrate.

Specifically, in the substrate treatment method, the alignment error of each of multiple alignment marks may be obtained according to the fourth model. Here, the alignment error obtained according to the fourth model may be an estimate. The estimate may be an expected value rather than a measured value. The alignment error obtained according to the fourth model may be referred to as the estimated alignment error. In the substrate treatment method, the selected substrate may be aligned in order for the estimated alignment error of multiple alignment marks to be minimized. For example, the selected substrate may be aligned in order for the mean value of the estimated alignment error of multiple alignment marks to be smaller.

In an example embodiment, operation S250 in which a position of the selected substrate is aligned may include performing translational movement on the selected substrate when the fourth model includes an offset component. In this case, each of the multiple alignment marks of the selected substrate may be moved in a direction and to a degree corresponding to the coefficient of the offset component.

In an example embodiment, operation S250 in which a position of the selected substrate is aligned may include bending the selected substrate (e.g., applying pressure to a portion of the selected substrate such that the selected substrate is deformed) in the vertical direction when the fourth model includes the scale component. In this case, each of the multiple alignment marks of the selected substrate may be moved according to the degree corresponding to the coefficient and coordinates of the scale component. Each of the multiple alignment marks may be moved by a different amount depending on the coordinates.

In an example embodiment, operation S250 in which a position of the selected substrate is aligned may include rotating the selected substrate when the fourth model includes the rotation component. In this case, each of the plurality of alignment marks of the selected substrate may be rotated clockwise or counterclockwise depending on the degree corresponding to the coefficient and coordinates of the rotation component.

In an example embodiment, the substrate treatment method may further include bonding the upper substrate to the lower substrate after a position of the selected substrate is aligned.

Specifically, in the substrate treatment method, a substrate selected between the upper substrate and the lower substrate may be aligned in order for the relative positions of the upper substrate and lower substrate to be adjusted in the direction of reducing the alignment error of the alignment marks of the upper substrate and lower substrate. Bonding may begin once the alignment is complete in order for the upper substrate and the lower substrate to be in a state facing each other. A variety of methods, such as heat, pressure, adhesives, lasers and ultrasound may be used for bonding (for example, hybrid bonding may be used in which materials of the upper substrate and lower substrate merge with each other). Once bonding is complete, the upper substrate and lower substrate may be physically joined to each other.

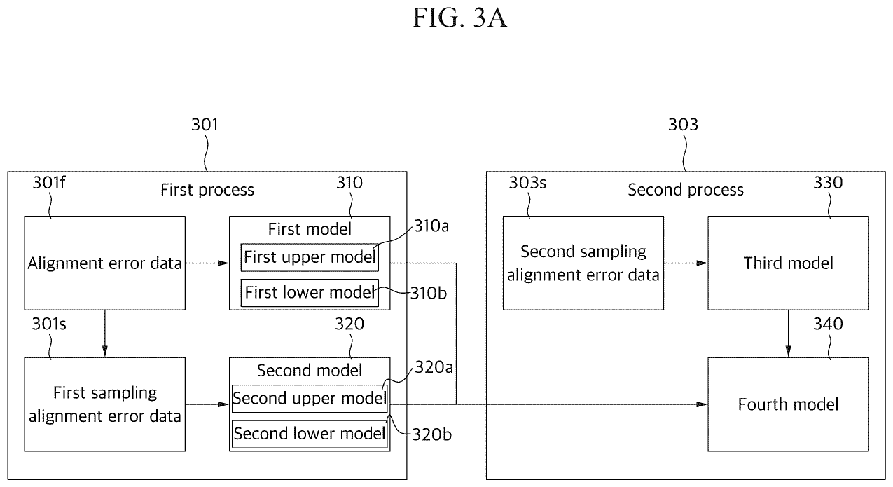

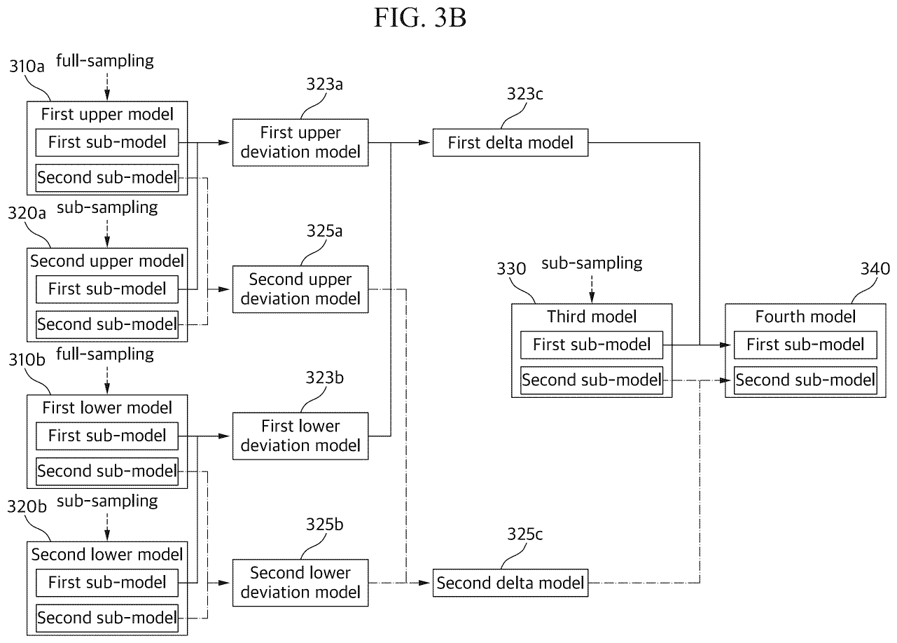

FIG. 3A is a diagram for explaining a model obtaining process according to an example embodiment. FIG. 3B is a diagram for explaining the process for obtaining a specific model according to an example embodiment.

Referring to FIG. 3A, the substrate treatment method may include first process 301 and second process 303. The substrate treatment method may perform the second process 303 after performing the first process 301. In an example embodiment, the substrate treatment method may perform the second process 303 immediately after the first process 301 is completed. In another example embodiment, in the substrate treatment method, once the first process 301 is completed, at least one other process may be performed, and after the at least one other process is completed, the second process 303 may be performed. In an example embodiment, the first process 301 may be the exposure process and the second process 303 may be the bonding process. However, this is a mere example embodiment, and the first process 301 and the second process 303 may be implemented in various different process.

In the substrate treatment method, alignment error data 301f for multiple alignment marks included in the substrate may be measured in the first process 301, and a first model 310 may be determined using the alignment error data 301f. In an example embodiment, in the substrate treatment method, a substrate may be aligned according to the first model 310 and a treatment may be performed on the aligned substrate corresponding to the first process 301.

Here, the alignment error data 301f may include a dataset for each of multiple alignment marks. The dataset for an alignment mark may include coordinates and alignment errors for the same alignment mark. For example, the dataset may include coordinates (x, y) for the first horizontal direction (for example, X-axis direction) and the second horizontal direction (for example, Y-axis direction), first alignment error dx in the first horizontal direction, and second alignment error dy in the second horizontal direction.

In the substrate treatment method, a second model 320 may be determined by obtaining first sampling alignment error data 301s for at least one alignment mark from the alignment error data 301f measured during the first process 301, and using the first sampling alignment error data 301s.

Here, the first sampling alignment error data 301s may include a dataset for each of at least one alignment mark among multiple alignment marks. The dataset for an alignment mark may include coordinates and alignment errors for the same alignment mark. Meanwhile, the first sampling alignment error data 301s may be obtained from the measured the alignment error data 301f. The second model 320 may be determined during the first process 301, or may be determined after the first process 301.

In an example embodiment, the number of at least one alignment mark for obtaining the first sampling alignment error data 301s may be smaller than the number of multiple alignment marks for obtaining the alignment error data 301f. In other words, the number of datasets for alignment marks included in the first sampling alignment error data 301s may be smaller than the number of datasets for alignment marks included in the alignment error data 301f.

In an example embodiment, the first model 310 may include a first upper model 310a and a first lower model 310b, and the second model 320 may include a second upper model 320a and a second lower model 320b. Here, the substrate may include an upper substrate and a lower substrate. The first upper model 310a may be the first model of the upper substrate, and the first lower model 310b may be the first model of the lower substrate. The second upper model 320a may be the second model of the upper substrate, and the second lower model 320b may be the second model of the lower substrate. The alignment error data for multiple alignment marks of the upper substrate may be used to determine the first upper model 310a, and the alignment error data for multiple alignment marks of the lower substrate may be used to determine the first lower model 310b. First sampling alignment error data for at least one alignment mark of the upper substrate may be used to determine the second upper model 320a, and the first sampling alignment error data for at least one alignment mark of the lower substrate may be used to determine the second lower model 320b.

After the first process 301 is completed, in the substrate treatment method, a third model 330 may be determined by measuring second sampling alignment error data 303s for at least one alignment mark among multiple alignment marks included in the substrate during the second process 303, and using the second sampling alignment error data 303s. In the substrate treatment method, a fourth model 340 may be determined by correcting the third model 330 using the difference between the second model 320 and the first model 310. In an example embodiment, in the substrate treatment method, the substrate may be aligned according to the fourth model 340, and the second process 303 may be performed on the aligned substrate.

Here, the second sampling alignment error data 303s may include a dataset for each of at least one alignment mark among the plurality of alignment marks. A dataset for an alignment mark may include coordinates and alignment errors for the same alignment mark.

In an example embodiment, the second sampling alignment error data 303s and the first sampling alignment error data 301s may include datasets for the same alignment mark or set of alignment marks. In an example embodiment, the number of at least one alignment mark for obtaining the second sampling alignment error data 303s may be smaller than the number of multiple alignment marks for obtaining the alignment error data 301f. In other words, the number of datasets for alignment marks included in the second sampling alignment error data 303s may be smaller than the number of datasets for alignment marks included in the alignment error data 301f. Because the second sampling alignment error data 303s and the first sampling alignment error data 301s may include datasets for the same alignment mark or set of alignment marks, the number of datasets for alignment marks included in the second sampling alignment error data 303s may be the same as the number of datasets for alignment marks included in the first sampling alignment error data 301s.

FIG. 3B is a diagram for explaining the process for obtaining a specific model according to an example embodiment.

Referring to FIG. 3A and FIG. 3B, the first model 310 may include the first upper model 310a for the upper substrate and the first lower model 310b for the lower substrate. The second model 320 may include the second upper model 320a for the upper substrate and the second lower model 320b for the lower substrate. The first upper model 310a may be determined through a full-sampling method for the upper substrate, and the second upper model 320a may be determined through the subsampling method for the upper substrate. The first lower model 310b may be determined through the full-sampling method for the lower substrate, and the second lower model 320b may be determined through the subsampling method for the lower substrate.

Each of the first model 310 to the fourth model 340 according to the example embodiments may include a first sub-model and a second sub-model. In an example embodiment, the first sub-model may be a sub-model representing the first alignment error (for example, dx) in the first horizontal direction (for example, X-axis direction) of the alignment mark. The second sub-model may be a sub-model representing the second alignment error (for example, dy) in the second horizontal direction (for example, Y-axis direction).

For example, the first sub-model of the first upper model 310a and the first lower model 310b may be determined using alignment error data for multiple alignment marks of the upper substrate and the lower substrate according to the full-sampling method. For example, the first sub-model of the second upper model 320a and the second lower model 320b may be determined using first sampling alignment error data for at least one alignment mark of the upper substrate and the lower substrate according to the subsampling method. In the same way, second sub-models of the first upper model 310a and the first lower model 310b and second sub-models of the second upper model 320a and the second lower model 320b may be determined using either the alignment error data or the first sampling alignment error data. Here, determining a model may indicate determining the model function and its coefficients statistically using alignment error data or sampling alignment error data.

The first sub-model may include at least one alignment error component among a first offset component, a first scale component for the first coordinate (for example, x-coordinate) in the first horizontal direction (for example, X-axis direction), and a first rotation component about the second coordinate (for example, y coordinate) in the second horizontal direction (for example, Y-axis direction). The second sub-model may include at least one alignment error component among a second offset component, a second scale component for the second coordinate (for example, y coordinate) in the second horizontal direction (for example, Y-axis direction) and a second rotation component about the first coordinate (for example, x-coordinate) in the first horizontal direction (for example, X-axis direction). Each alignment error component may include a coefficient. The coefficient may be a value determined based on alignment error data or sampling alignment error data.

In an example embodiment, the first horizontal direction and the second horizontal direction may be X-axis direction and Y-axis direction. The X-axis direction and the Y-axis direction are perpendicular to each other and may be direction axes perpendicular to the height direction (for example, Z-axis direction).

The first offset component indicates the degree to which the alignment mark is misaligned in the first horizontal direction (for example, X-axis direction) according to the coefficient. The second offset component indicates the degree to which the alignment mark is misaligned in the second horizontal direction (for example, Y-axis direction) according to the coefficient. For example, the first offset component may be “k1” and the second offset component may be “l1.”

The first rotation component and the second rotation component indicate the degree to which the alignment mark is misaligned clockwise or counterclockwise. In an example embodiment, the first rotation component with respect to the second coordinate (for example, the y-coordinate) indicates the degree to which the alignment mark is misaligned in the first horizontal direction (for example, the X-axis direction) depending on the coefficient and the second coordinate (for example, the y-coordinate). For example, the first rotation component could be “k2×y.” In an example embodiment, the second rotation component with respect to the first coordinate (for example, the x-coordinate) indicates the degree to which the alignment mark is misaligned in the second horizontal direction (for example, the Y-axis direction) with respect to the coefficient and the first coordinate (for example, the x-coordinate). For example, the second rotation component could be “l2×x.”

The first scale component indicates the degree to which the alignment mark is misaligned in the first horizontal direction (for example, X-axis direction) according to the first coordinate (for example, x-coordinate) and coefficient. The second scale component indicates the degree to which the alignment mark is misaligned along the second horizontal direction (for example, the Y-axis direction) according to a second coordinate (for example, the y-coordinate) and the coefficient.

In an example embodiment, the first scale component may include an nth degree polynomial with respect to the first coordinate in the first horizontal direction. The second scale component may include an mth degree polynomial for the second coordinate in the second horizontal direction. Here, each of n and m may be an integer greater than or equal to 1. In an example embodiment, the nth degree polynomial for the first coordinate (for example, the x-coordinate) may be the first-degree polynomial of “k3×x.” In another example embodiment, nth degree polynomial may be the second degree polynomial of “k3×x+k4×x².” Meanwhile, the mth degree polynomial for the second coordinate (for example, the y coordinate) may be a first degree polynomial of “l3×y.” In another example embodiment, the mth degree polynomial may be a second degree polynomial of “l3×y+l4×y².” However, this is a mere example embodiment, and the nth degree polynomial and mth degree polynomial may each be transformed into polynomials of various degrees when implemented, such as a 3rd degree polynomial.

In an example embodiment, as an independent variable, the coefficient of the alignment error component included in the first sub-model may be determined using regression analysis based on the first coordinate in the first horizontal direction (for example, the x-coordinate) and the second coordinate in the second horizontal direction (for example, the y-coordinate) for each of the plurality of alignment marks set, and the first alignment error in the first horizontal direction for each of the multiple alignment marks that is set as a dependent variable (for example, dx). The independent variable is a variable that affects the dependent variable that is to be predicted, and the dependent variable is a variable whose value changes depending on changes in the independent variable.

In an example embodiment, the coefficient of the alignment error component included in the second sub-model may be determined using the regression analysis based on the first coordinate in the first horizontal direction (for example, the x-coordinate) and the second coordinate in the second horizontal direction (for example, the y-coordinate) for each of the multiple alignment marks that are set as independent variables, and the second alignment error in the second horizontal direction for each of multiple alignment marks that is set as a dependent variable (for example, dy).

For example, example embodiments are described based on the process of determining the first sub-model of the first upper model 310a using the regression analysis. Here, the first sub-model includes the first offset component, the first rotation component and the first scale component of the first degree polynomial.

In an example embodiment, in the substrate treatment method, alignment error data for multiple alignment marks of the upper substrate may be obtained. The alignment error data may include the coordinates and the alignment error for each alignment mark. The alignment error data may include a first dataset (x1, y1, dx1) for the first alignment mark, a second dataset (x2, y2, dx2) for the second alignment mark, and a third dataset (x3, y3, dx3) for the third alignment mark. Meanwhile, the number of datasets may vary widely. For example, the number of datasets in the full-sampling method may be greater than the number of datasets in the subsampling method. The alignment error data may be expressed as a matrix of the following Equation 1 depending on the properties of the data.

$$DX = [ \begin{matrix}dx 1 \\ dx 2 \\ dx 3\end{matrix} ] , A = [ \begin{matrix}1 & y 1 & x 1 \\ 1 & y 2 & x 2 \\ 1 & y 3 & x 3\end{matrix} ] , K = [ \begin{matrix}k 1 \\ k 2 \\ k 3\end{matrix} ] \qquad [ Equation 1 ]$$

Here, DX is a matrix for alignment error of alignment marks, and A is a matrix of coordinates of alignment marks. K is a matrix for the coefficient k1 of the first offset component, the coefficient k2 of the first rotation component, and the coefficient k3 of the first scale component. K may be calculated using the linear regression equation of Equation 2 or Equation 3 below.

$$DX = A \cdot K \qquad [ Equation 2 ]$$

$$K = {( {A}^{T} \cdot A )}^{- 1} \cdot {A}^{T} \cdot DX \qquad [ Equation 3 ]$$

In this case, the first sub-model applying K may be a model function of the following Equation 4. Here, x and y are the coordinates of the first horizontal direction and the second horizontal direction of the alignment mark, and dx is the alignment error in the first horizontal direction. When the coordinates of each alignment mark are input into the first sub-model, the alignment error for each alignment mark is obtained as an output value. Meanwhile, the method may be applied when determining the first sub-model and the second sub-model of the first model 310 to the third model 330 using alignment error data or sampling alignment error data.

$$dx = k 1 + k 2 \times y + k 3 \times x \qquad [ Equation 4 ]$$

In an example embodiment, referring to FIG. 2 and FIG. 3B, operation S240 in which the fourth model is determined by correcting the third model using the difference between the second model and the first model may include obtaining a first upper deviation model 323a, obtaining a first lower deviation model 323b, obtaining a first delta model 323c, and obtaining the first sub-model of the fourth model. Meanwhile, operation S240 in which the fourth model is determined by correcting the third model using the difference between the second model and the first model may include obtaining a second upper deviation model 325a, obtaining a second lower deviation model 325b, obtaining a second delta model 325c, and obtaining the second sub-model of the fourth model.

In an example embodiment, the first upper deviation model 323a may be a model that is the difference (e.g., a first upper difference) between the first sub-model of the second upper model 320a and the first sub-model of the first upper model 310a. For example, when the first sub-model of the second upper model 320a is “dx=ka1+ka2×y+ka3×x” and the first sub-model of the first upper model 310a is “dx=kb1+kb2×y+kb3×x,” the first upper deviation model 323a may be “dx=(ka1−kb1)+(ka2−kb2)×y+(ka3−kb3)×x.” In other words, the first upper deviation model 323a may be a model with coefficient differences between the same alignment components.

The first lower deviation model 323b may be a model that is the difference (e.g., a first lower difference) between the first sub-model of the second lower model 320b and the first sub-model of the first lower model 310b. The description of the first upper deviation model 323a may be equally applied thereto.

The first delta model 323c may be a model obtained by utilizing the difference between the first upper deviation model 323a and the first lower deviation model 323b. In an example embodiment, to proceed with the bonding process, one of the upper substrate and the lower substrate may be flipped in order for the upper substrate and the lower substrate to face each other. When the upper substrate is flipped around the second horizontal direction as the rotation axis, with respect to the model of which the first upper deviation model 323a is flipped, the signs of the first offset component and the first rotation component may change. For example, when the first upper deviation model 323a is “dx=(ka1−kb1)+(ka2−kb2)×y+(ka3−kb3)×x,” some signs may change when the upper substrate is flipped, such as “dx=−(ka1−kb1)−(ka2−kb2)×y+(ka3−kb3)×x” with regard to the flipped model. In an example embodiment, in a flipped model, in the case of the first scale component, for polynomials of even degree, the sign may be changed, and for polynomials of odd degree, the sign may be maintained. Meanwhile, in the case of the first lower deviation model 323b for the lower substrate that is not flipped, the sign of the alignment error component may be maintained. In this case, the first delta model 323c may be a model representing the difference between a flipped model of the first upper deviation model 323a and the first lower deviation model 323b.

The first sub-model of the fourth model may be a model that is the difference between the first sub-model of the third model 330 and the first delta model 323c. The description for the first upper deviation model 323a may be equally applied thereto.

Meanwhile, the second upper deviation model 325a may be a model that is the difference between the second sub-model of the second upper model 320a and the second sub-model of the first upper model 310a. The second lower deviation model 325b may be a model that is the difference between the second sub-model of the second lower model 320b and the second sub-model of the first lower model 310b. The description for the first upper deviation model 323a may be equally applied thereto.

The second delta model 325c may be a model obtained by utilizing the difference between the second upper deviation model 325a and the second lower deviation model 325b. In an example embodiment, when the upper substrate is flipped around the second horizontal direction as the rotation axis, in the model where the second upper deviation model 325a is flipped, the sign of the second rotation component changes, and the signs of the second offset component and second scale component are maintained. Further, in the case of the second lower deviation model 325b for the lower substrate that is not flipped, the sign of the alignment error component may be maintained. In this case, the second delta model 325c may be a model representing the difference between a flipped model of the second upper deviation model 325a and the second lower deviation model 325b.

The second sub-model of the fourth model may be a model that is the difference between the second sub-model of the third model 330 and the second delta model 325c. The description of the first upper deviation model 323a may be equally applied thereto.

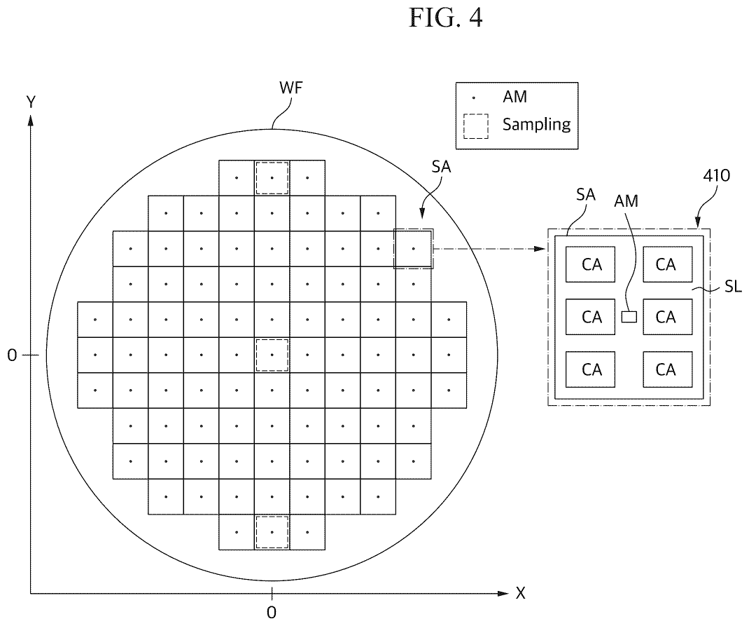

FIG. 4 is a drawing for explaining a substrate according to an example embodiment.

Referring to FIG. 4, in the substrate treatment method, the exposure process is performed on a substrate WF. Here, the substrate WF may be either the upper substrate or the lower substrate. The substrate WF may include multiple shot areas SA. Each of the multiple shot areas SA may represent an area to be exposed. The multiple shot areas SA may be arranged along the first horizontal direction (for example, X-axis direction) and the second horizontal direction (for example, Y-axis direction).

Referring to an enlarged area 410 of FIG. 4, the shot area SA may include multiple chip areas CA. The chip area CA may be an area where an independent semiconductor structure is formed. A scribe lane SL may be formed between the chip areas CA. When the chip area CA is individually separated by a laser or diamond blade, the area cut in the substrate WF may be the scribe lane SL.

One or more of the shot areas SA may include an alignment mark AM. The alignment mark AM may be a reference point used to identify and align the position of the substrate WF or the shot area SA for precise patterning during the exposure process. The alignment mark AM may be detected by a sensor such as a camera and laser. The alignment mark AM may be formed as a structure having a specific shape or a specific color.

Meanwhile, in the substrate treatment method, using the full-sampling method, the substrate WF may be aligned by measuring alignment error data for the entire alignment marks AM or multiple alignment marks AM (e.g., all of the alignment marks AM) included in the substrate WF. Further, in the substrate treatment method, the substrate WF may be aligned by measuring alignment error data for a small number of the alignment marks AM among all alignment marks AM included in the substrate WF according to the subsampling method.

In an example embodiment, in the substrate treatment method, during the first process (e.g., exposure process) that requires high precision, the substrate WF may be aligned by measuring alignment error data according to the full-sampling method. Further, in the substrate treatment method according to some example embodiments, during the second process after the first process, when sampling alignment error data according to the subsampling method is measured, the alignment accuracy may be improved by utilizing alignment error data measured according to the full-sampling method during the first process. According thereto, even in the case of a device that performs a second process with lower sensing or computational capabilities than a device that performs the first process (for example, the exposure apparatus), the alignment accuracy of the substrate WF may be improved. Further, even in the case where the sensing or computing capability of the device performing the second process is sufficient, the alignment accuracy may be improved by utilizing alignment error data according to the full-sampling method measured during the first process, and at the same time, sorting speed may be improved.

In an example embodiment, the number of at least one alignment mark according to the subsampling method may be smaller than the number of multiple alignment marks according to the full-sampling method. For example, the number of at least one alignment mark according to the subsampling method may be set to 1. However, it is a mere example embodiment. The number of the at least one alignment mark depending on the subsampling method may be varied to various values such as 2, 3, and so on when implemented. The number of multiple alignment marks according to the full-sampling method may be set to the total number of multiple alignment marks, or may be set to a number greater than the number of at least one alignment mark according to the subsampling method.

In an example embodiment, at least one alignment mark according to the subsampling method may include an alignment mark located at a center area of each of the upper substrate and the lower substrate. For example, at least one alignment mark according to the subsampling method may include an alignment mark having coordinates of (0, 0).

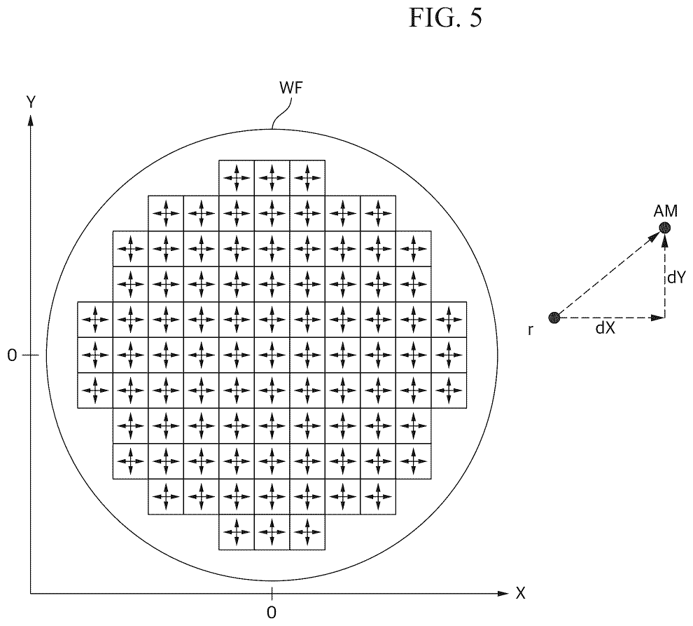

FIG. 5 is a diagram for explaining alignment error data according to an example embodiment.

Referring to FIG. 4 and FIG. 5, according to the full-sampling method, alignment error data for the entire alignment marks AM (e.g., all of the alignment marks AM) of the substrate WF may be obtained.

The alignment error data may include coordinates and alignment errors for each alignment mark AM. The coordinates may indicate the position of the alignment mark AM with respect to a specific direction. The coordinates for the alignment mark AM may include a first coordinate in the first horizontal direction (for example, X-axis direction), and a second coordinate in the second horizontal direction (for example, Y-axis direction). The alignment error may indicate the degree of mismatch between the measurement position of the alignment mark AM and the target point (r). The alignment error may include first alignment error (for example, dx) in the first horizontal direction (for example, X-axis direction), and the second alignment error (for example, dy) in the second horizontal direction (for example, Y-axis direction). The target point (r) may be a reference position that is set for each process. The measured location of the alignment mark AM is compared to the known location of the target point (r) to determine the alignment error. Meanwhile, the alignment error may be represented as an arrow that is a combination of a first alignment error and a second alignment error.

In an example embodiment, alignment errors may result from mechanical alignment inaccuracies when moving or fixing the substrate WF. The alignment errors may occur due to the substrate WF being warped or deformed by the heat generated during the process. The alignment errors may occur when a process (for example, the exposure process) is performed while the substrate WF is not aligned accurately.

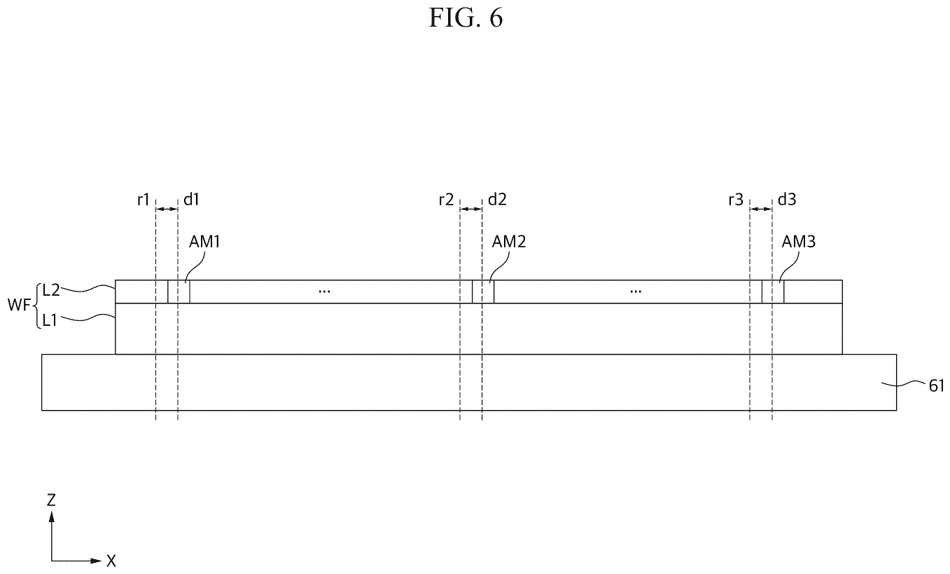

FIG. 6 is a drawing for explaining a cross-section of a substrate according to an example embodiment.

Referring to FIG. 6, the substrate WF may include a first layer L1 and a second layer L2. The second layer L2 may be a layer located at the upper portion of the first layer L1 in the height direction (for example, the Z-axis direction). In an example embodiment, the second layer L2 may be the uppermost portion layer within the substrate WF. A plurality of alignment marks AM1 to AM3 may be formed in the second layer L2. However, it is a mere example embodiment, and the layer structure and the positions where the multiple alignment marks AM1 to AM3 are formed may be varied when implemented.

In the substrate treatment method, the substrate WF may be aligned on a stage 61 to perform a process on the substrate WF. The stage 61 may be included in the exposure apparatus 10a. For example, in the substrate treatment method, the substrate WF may be loaded into the initial position on the stage 61, and an alignment error between the multiple alignment marks AM1 to AM3 and corresponding target points r1 to r3 may be measured. In the substrate treatment method, the substrate WF may be aligned in a way that alignment error is minimized. In this case, in the substrate treatment method, the substrate WF may be aligned in order for the sum or mean value of the alignment errors of each of the multiple alignment marks AM1 to AM3 to be minimized.

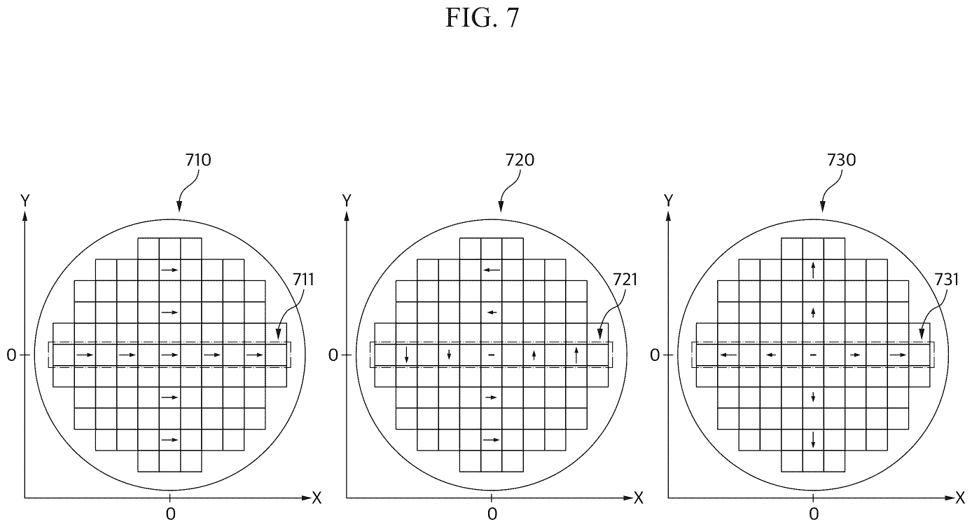

FIG. 7 is a drawing for explaining the alignment error of a substrate according to an example embodiment.

Referring to FIG. 7, the arrows for each of a first substrate 710 and a third substrate 730 indicates alignment error of the alignment mark, and the arrows indicate only a portion of the total area of each substrate, with the rest omitted.

It is identified that when an X-axis area 711 of the first substrate 710 is sampled, when proceeding in the +X-axis direction, multiple arrows are pointing to the same +X-axis direction, and the arrows are the same size. In other words, the first alignment error has a constant size regardless of the first coordinate, and this may indicate that the same size offset occurred on the first substrate 710 with +X-axis direction. In this case, the first sub-model for X-axis direction could be “dx=k1.” Here, k1 is a value greater than 0.

It is identified that when an X-axis area 721 of a second substrate 720 is sampled, when proceeding in the +X-axis direction, multiple arrows change from −Y-axis direction to +Y-axis direction, and the size of the arrow increases when moving away from the center area. This may indicate that a counterclockwise rotation occurred at the second substrate 720. In other words, the second alignment error may depend on the first coordinate. In this case, second sub-model for Y-axis direction may be “dy=k2×x.” Here, k2 is a value greater than 0.

It is identified that when an X-axis area 731 of the third substrate 730 is sampled, when proceeding in the +X-axis direction, multiple arrows change from −X-axis direction to +X-axis direction, and size of the arrow increases when moving away from the center area. This may indicate that a deformation occurred in the third substrate 730. In other words, the first alignment error may depend on the first coordinate. In this case, the first sub-model for X-axis direction could be “dx=k3×x.” Here, k3 is a value greater than 0.

Meanwhile, the alignment errors of the first substrate 710, the second substrate 720 and the third substrate 730 may appear in combination. In this case, as the number of samples decreases, it may become more difficult to ensure alignment accuracy. In the substrate treatment method, the effect of improving alignment accuracy is obtained by combining the subsampling method, which measures a small number of alignment marks, with the full-sampling method, which measures a large number of alignment marks.

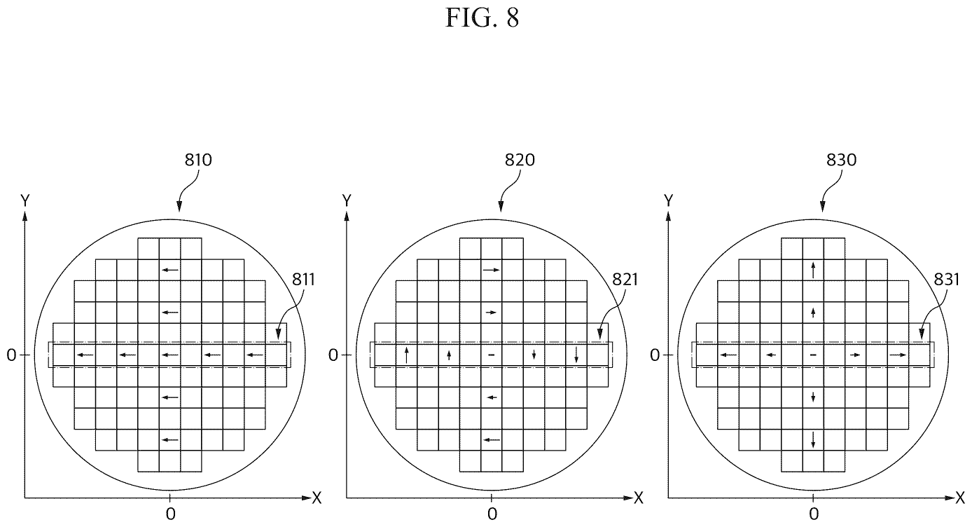

FIG. 8 is a drawing for explaining alignment error of a flipped substrate according to an example embodiment.

Referring to FIG. 7 and FIG. 8, a first flipped substrate 810 to a third flipped substrate 830 may be the first substrate 710 to the third substrate 730 that are flipped 180 degrees along the Y-axis, respectively. In this case, the signs related to X-axis direction may change. For example, the signs of odd-degree polynomials for dx and x may be changed.

In an example embodiment, when the first sub-model of the first substrate 710 is “dx=k1,” the first sub-model of the first flipped substrate 810 may be changed to “dx=−k1.” For example, for the X-axis areas 711 and 811, the first alignment error (for example, the direction of the rotated arrow) may change from +X-axis direction to −X-axis direction due to the rotation (e.g., the flipping of the first substrate).

In an example embodiment, when the second sub-model of the second substrate 720 is “dy=k2×x,” first sub-model of a second flipped substrate 820 may be changed to “dy=−k2×x.” For example, in the case of the X-axis areas 721 and 821, the sign of the first coordinate may change depending on the rotation. Meanwhile, the direction of the arrow may maintain +Y-axis direction.

In an example embodiment, when the first sub-model of the third substrate 730 is “dx=k3×x,” the first sub-model of the third flipped substrate 830 may be maintained as “dx=k3×x.” In the case of the X-axis areas 721 and 821, the sign of the first coordinate may change depending on the rotation, and the first alignment error (for example, the direction of the rotated arrow) may change from +X-axis direction to −X-axis direction.

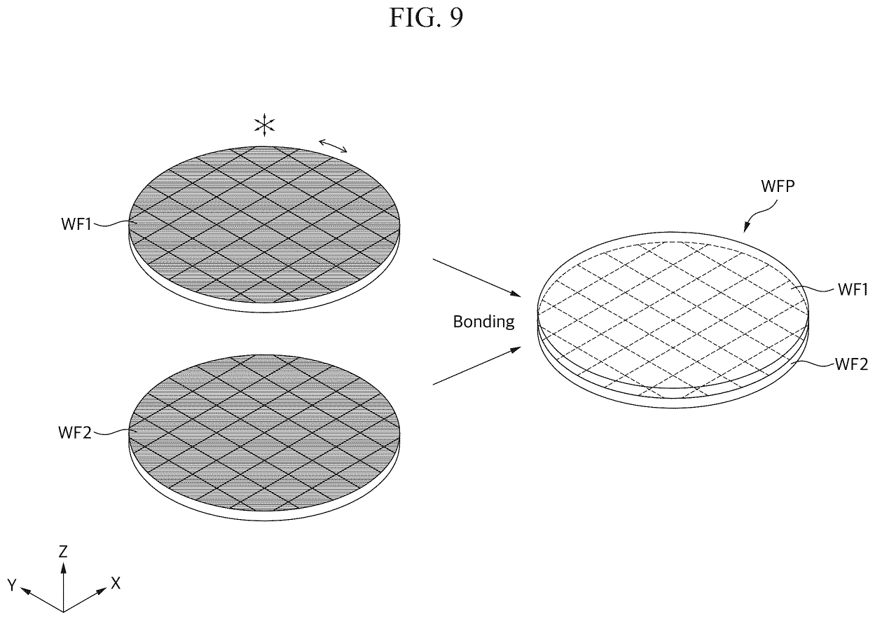

FIG. 9 is a drawing to explain bonding an upper substrate to a lower substrate according to an example embodiment.

Referring to FIG. 9, in the substrate treatment method, a substrate assembly WFP may be formed by bonding an upper substrate WF1 to a lower substrate WF2. Bonding may be used to manufacture semiconductor devices such as flash memory, DRAM, HBM and logic. The substrate assembly WFP may be a structure in which the upper substrate WF1 and the lower substrate WF2 are bonded to each other.

In the substrate treatment method, alignment error data may be measured for each of the upper substrate WF1 and the lower substrate WF2 to align an upper surface of each of the upper substrate WF1 and the lower substrate WF2 to face the upper portion direction (for example, +Z-axis direction), and to proceed with the first process (for example, exposure process) for each of the upper substrate WF1 and the lower substrate WF2.

Then, in the substrate treatment method, the upper substrate WF1 may be flipped and rotated 180 degrees, sampling alignment error data for the upper substrate WF1 and the lower substrate WF2 may be measured, and the upper surface of the upper substrate WF1 may be aligned so as to face the negative height direction (in other words, the lower portion direction). Further, in the substrate treatment method, the upper substrate WF1 and the lower substrate WF2 may be bonded. A variety of methods, including heat, pressure, adhesives, lasers and ultrasound may be used for bonding.

For example, in the substrate treatment method, the selected substrate among the upper substrate WF1 and the lower substrate WF2 may be aligned according to the fourth model obtained by correcting the third model using the difference between the second model and the first model. Specifically, in the substrate treatment method, following the fourth model, the alignment error of each of multiple alignment marks may be obtained, and the selected substrate may be aligned so that the estimated alignment error of multiple alignment marks is minimized. In this case, in the substrate treatment method, the selected substrate may be aligned such that the estimated alignment error of multiple alignment marks is minimized by performing translational movement on the selected substrate in the first horizontal direction (for example, X-axis direction) and/or the second horizontal direction (for example, Y-axis direction), rotating clockwise or counterclockwise, a method of bending a portion of the selected substrate in the height direction (for example, Z-axis direction), or a combination thereof. Below, example embodiments are described in which alignment is performed when the selected substrate is the upper substrate WF1.

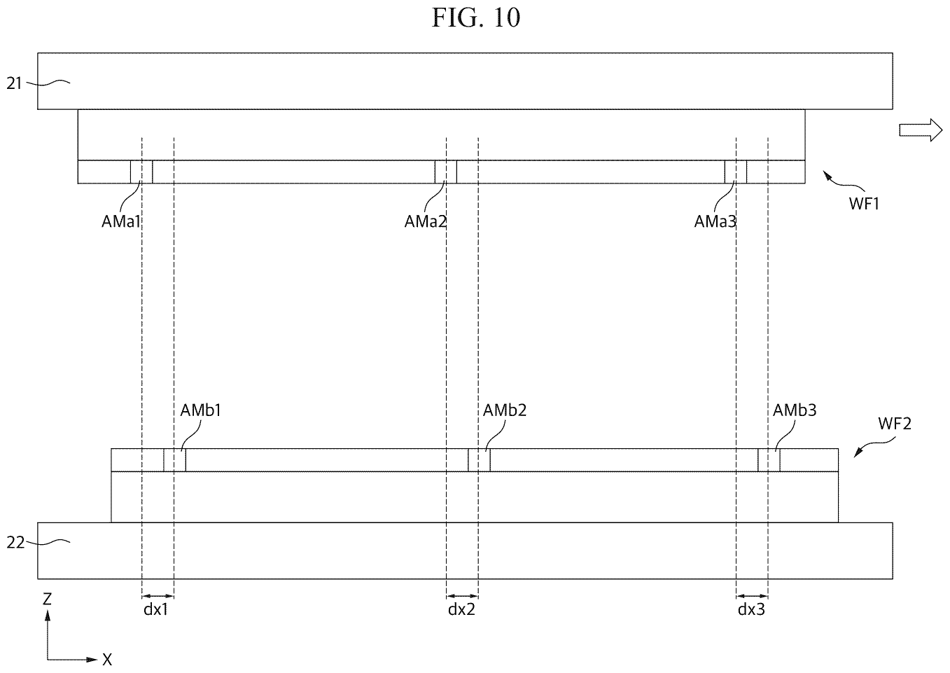

FIGS. 10 to 12 are drawings for explaining the alignment of the upper substrate and the lower substrate according to an example embodiment. FIGS. 10 to 12 sequentially illustrate operations for aligning a substrate by performing a translational movement when offset occurs.

Referring to FIG. 10 to FIG. 12, in the substrate treatment method, during the second process after the first process, the upper substrate WF1 and the lower substrate WF2 may be loaded onto an upper stage 21 and a lower stage 22, respectively. For example, the first process may be the exposure process, and the second process may be the bonding process.

For example, in the substrate treatment method, the upper substrate WF1 may be loaded onto the upper stage 21 in order for the upper substrate WF1 and the lower substrate WF2 to face each other, and the lower substrate WF2 may be loaded onto the lower stage 22. The upper stage 21 and the lower stage 22 may be included in the bonding apparatus 20. The upper substrate WF1 may include multiple alignment marks, and the plurality of alignment marks may include first to third upper alignment marks AMa1 to AMa3. The lower substrate WF2 may include multiple alignment marks, and the plurality of alignment marks may include first to third lower alignment marks AMb1 to AMb3. Example embodiments are described assuming that the first to third upper alignment marks AMa1 to AMa3 and the first to third lower alignment marks AMb1 to AMb3 are the measurement targets of the alignment error of the subsampling method.

In the substrate treatment method, second sampling error data may be obtained by measuring the alignment error between corresponding alignment marks of the upper substrate WF1 and the lower substrate WF2. In an example embodiment, the second sampling error data may include a first alignment error for the first horizontal direction (for example, X-axis direction) between the first upper alignment mark AMa1 and first lower alignment mark AMb1, a second alignment error for the first horizontal direction (for example, X-axis direction) between the second upper alignment mark AMa2 and the second lower alignment mark AMb2, and a third alignment error for the first horizontal direction (for example, X-axis direction) between the third upper alignment mark AMa3 and the third lower alignment mark AMb3. For example, the first alignment error may be “dx1,” the second alignment error may be “dx2” and the third alignment error may be “dx3.” In an example embodiment, the second sampling error data may further include alignment errors for the second horizontal direction (for example, Y-axis direction) between alignment marks corresponding to each other.

In the substrate treatment method, the third model may be determined using the second sampling error data. In the substrate treatment method, the first model and the second model may be determined by using the alignment error data for multiple alignment marks of each of the upper substrate WF1 and the lower substrate WF2 measured previously and first sampling alignment error data taken from the previously measured alignment error data. In the substrate treatment method, the fourth model may be determined by correcting the third model using the difference between the second model and the first model. Specific details on this will be omitted to avoid duplication.

In the substrate treatment method, alignment errors may be obtained depending on the fourth model. Here, the fourth model may include a first sub-model for alignment error in the first horizontal direction. Meanwhile, the fourth model may further include a second sub-model for alignment error in the second horizontal direction. In the following, example embodiments assume that the fourth model includes only the first sub-model, and the first sub-model is “dx=−k1,” where k1 is a value greater than 0. In this case, the first sub-model of the fourth model may include an offset component that is independent of the position of the alignment mark. The offset component may indicate that each alignment mark is misaligned to the same degree in the same direction. In the substrate treatment method, alignment may be performed by translational movement of the selected substrate, the upper substrate WF1, in the +X-axis direction opposite to the sign of the alignment error (for example, “−k1”) by the amount of the alignment error. For example, in the substrate treatment method, the translational movement may be performed on the upper stage 21 loaded with the upper substrate WF1 in order for the upper substrate WF1 to be aligned.

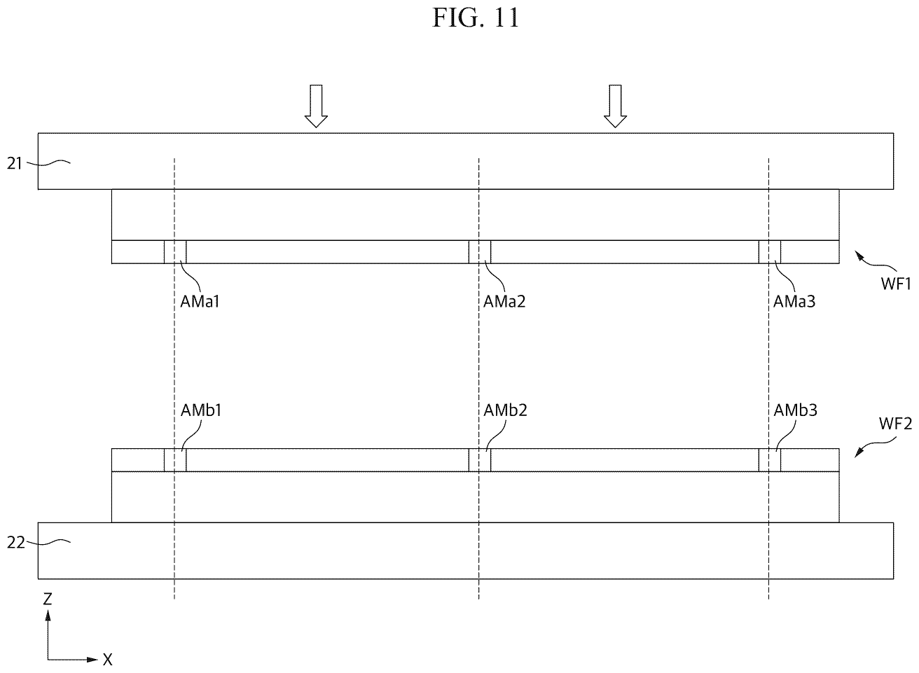

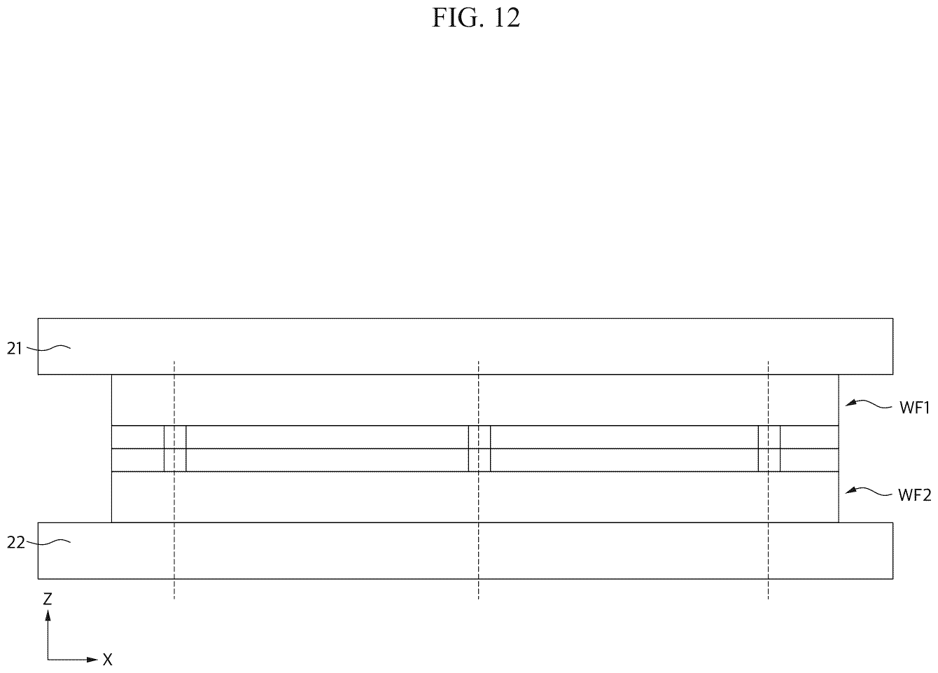

Then, referring to FIG. 11 and FIG. 12, in the substrate treatment method, at least one of the upper stage 21 and the lower stage 22 may be moved vertically in order for the upper substrate WF1 and the lower substrate WF2 to come into contact with each other, and when the upper substrate WF1 and the lower substrate WF2 are in contact with each other, the upper substrate WF1 and the lower substrate WF2 may be bonded.

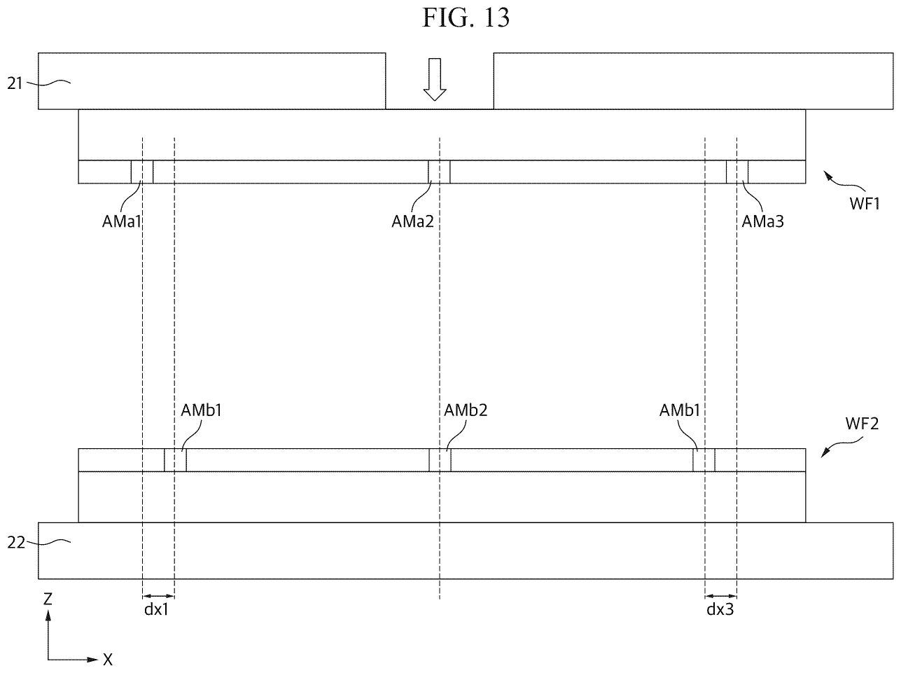

FIGS. 13 to 15 are drawings for explaining the alignment of the upper substrate and the lower substrate according to an example embodiment. FIGS. 13 to 15 sequentially illustrate operations for aligning a substrate by bending the substrate when deformation occurs.

Referring to FIG. 13 to FIG. 15, in the substrate treatment method, during the second process after the first process, the upper substrate WF1 and the lower substrate WF2 may be loaded onto the upper stage 21 and the lower stage 22, respectively. For example, the first process may be the exposure process and the second process may be the bonding process. In an example embodiment, an area of the upper stage 21 where the upper substrate WF1 is loaded may be opened. In other words, a hole may be formed in one area of the upper stage 21. For example, one area may be the center area, but may be changed to different areas.

In the substrate treatment method, the second sampling error data may be obtained by measuring the alignment error between corresponding alignment marks of the upper substrate WF1 and the lower substrate WF2. In an example embodiment, the second sampling error data may include first alignment error for the first horizontal direction (for example, X-axis direction) between the first upper alignment mark AMa1 and first lower alignment mark AMb1, second alignment error for the first horizontal direction (for example, X-axis direction) between the second upper alignment mark AMa2 and the second lower alignment mark AMb2, and third alignment error in the first horizontal direction (for example, X-axis direction) between the third upper alignment mark AMa3 and the third lower alignment mark AMb3. For example, the first alignment error may be “dx1,” the second alignment error may be 0, and the third alignment error may be “dx3.” In an example embodiment, the second sampling error data may further include alignment errors in the second horizontal direction (for example, Y-axis direction) between alignment marks corresponding to each other.

In the substrate treatment method, the third model may be determined using the second sampling error data. In the substrate treatment method, the first model and the second model may be determined using the alignment error data for multiple alignment marks of each of the upper substrate WF1 and the lower substrate WF2 measured previously and the first sampling alignment error data. In the substrate treatment method, the fourth model may be determined by correcting the third model using the difference between the second model and the first model. Specific details on this will be omitted to avoid duplication.

In the substrate treatment method, the alignment error may be obtained according to the fourth model. Here, the fourth model may include a first sub-model for alignment error in the first horizontal direction. Meanwhile, the fourth model may further include a second sub-model for alignment error in the second horizontal direction.

In the following, example embodiments assume that the fourth model includes only the first sub-model, and the first sub-model is “dx=k3×x,” where k3 is a value greater than 0. In this case, the first sub-model of the fourth model may include a first scale component for the first coordinate in the first horizontal direction. In other words, the first scale component may indicate that each alignment mark is misaligned to a different degree with respect to the first coordinate of the alignment mark. In the substrate treatment method, when the coefficient “k3” for the first scale component is greater than 1, it may be determined that the spacing between the alignment marks of the selected substrate, the upper substrate WF1, is greater than the spacing between the alignment marks of the lower substrate WF2. In this case, in the substrate treatment method, by bending the upper substrate WF1, the spacing between alignment marks on the upper substrate WF1 may be reduced to be the same as the spacing between alignment marks on the lower substrate WF2. In an example embodiment, by pressing the upper substrate WF1 toward in the direction of the lower portion through the hole of the upper stage 21, the upper substrate WF1 may be bent. Here, applied may be various pressurization methods such as a method of pressurizing the upper substrate WF1 by a pressurizing pin inserted through a hole and a method of pressurizing the upper substrate WF1 by air injected through the hole.

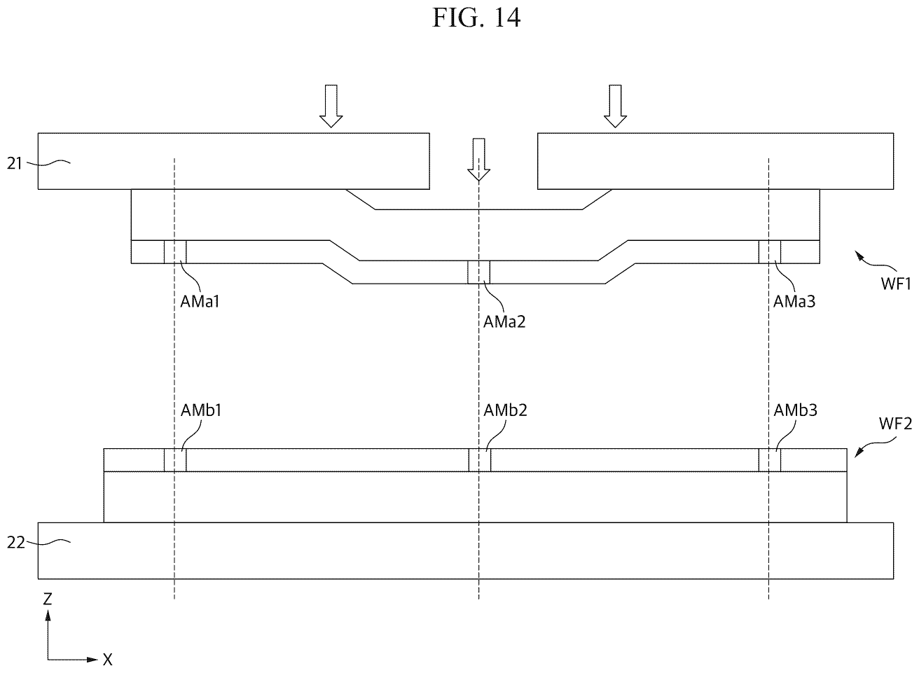

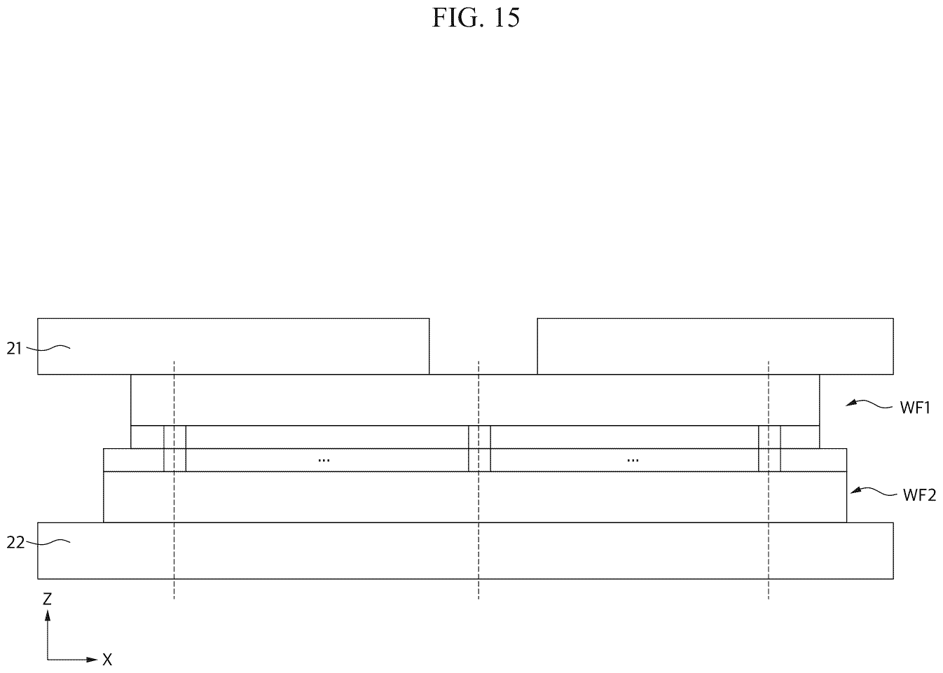

Then, referring to FIG. 14 and FIG. 15, in the substrate treatment method, at least one of the upper stage 21 and the lower stage 22 may be moved vertically in order for the upper substrate WF1 and the lower substrate WF2 to come into contact with each other, and when the upper substrate WF1 and the lower substrate WF2 are in contact with each other, the upper substrate WF1 and the lower substrate WF2 may be bonded.

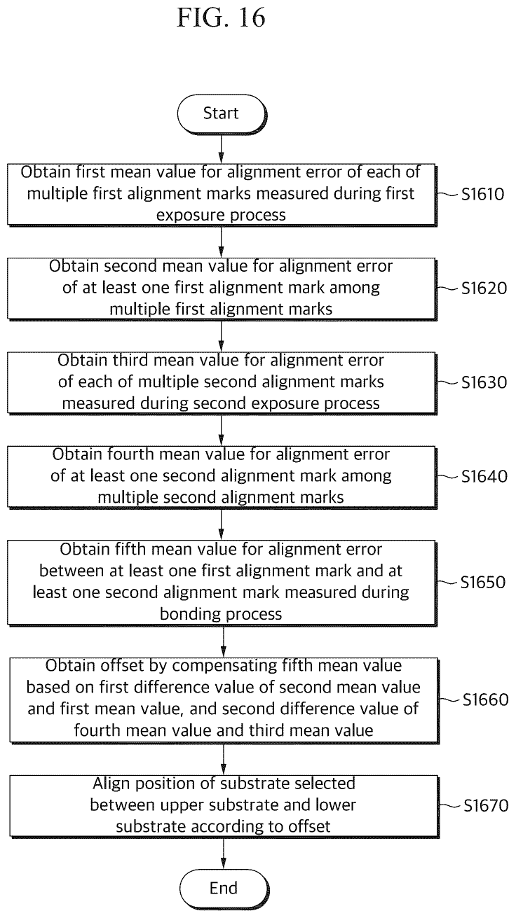

FIG. 16 is a flowchart for explaining a substrate treatment method according to an example embodiment.

Referring to FIG. 16, the substrate treatment method may include operation S1610 in which, a first mean value is obtained for the alignment error of each of the multiple first alignment marks measured during the first exposure process, operation S1620 in which a second mean value for the alignment error of at least one first alignment mark among multiple first alignment marks is obtained, operation S1630 in which a third mean value is obtained for the alignment error of each of the multiple second alignment marks measured during the second exposure process, operation S1640 in which a fourth mean value for the alignment error of at least one second alignment mark among the multiple second alignment marks is obtained, operation S1650 in which a fifth mean value is obtained for the alignment error between at least one first alignment mark and at least one second alignment mark measured during the bonding process of the upper substrate and the lower substrate, operation S1660 in which offset is obtained by compensating the fifth mean value using the first difference value between the second mean value and the first mean value, and using the second difference value between the fourth mean value and the third mean value, and operation S1670 in which the position of the substrate selected between the upper substrate and lower substrate is aligned according to the offset.

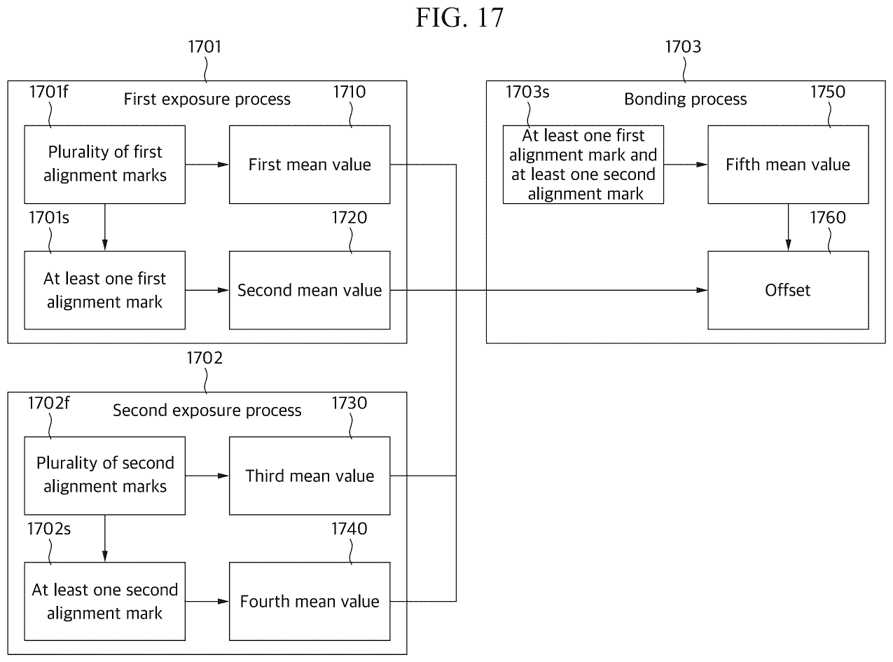

In the case of a mean value, a difference value, and offset according to the example embodiments of the present disclosure, direction-specific values may be included. In other words, each of the mean value, the difference value, and the offset may include one or multiple values depending on the direction. Specific details of each operation are explained together with reference to FIG. 17.

FIG. 17 is a drawing for explaining a process of obtaining offset according to an example embodiment.

Referring to FIG. 16 and FIG. 17, the substrate treatment method may include operation S1610 in which a first mean value 1710 for the alignment error of each of the multiple first alignment marks 1701f measured during the first exposure process 1701 is obtained.

The first exposure process 1701 may be the exposure process for the upper substrate. The upper substrate may include the multiple first alignment marks 1701f. The alignment error for each of the first alignment marks 1701f may include at least one of a first alignment error in the first horizontal direction (for example, X-axis direction) and a second alignment error in the second horizontal direction (for example, Y-axis direction). The first alignment error may represent the difference in coordinates in the first horizontal direction (for example, X-axis direction) between the first alignment mark and the target point, and the second alignment error may represent the difference in coordinates in the second horizontal direction (for example, Y-axis direction) between the first alignment mark and the target point.

The first mean value 1710 of the alignment errors of the plurality of first alignment marks 1701f may include at least one of a first sub mean value of first alignment errors and a second sub mean value of second alignment errors.

The substrate treatment method may include operation S1620 in which a second mean value 1720 for the alignment error of at least one first alignment mark 1701s among the multiple first alignment marks 1701f is obtained.

At least one first alignment mark 1701s may be selected from the plurality of first alignment marks 1701f to obtain the second mean value 1720 of the subsampling method. In other words, the alignment error of at least one of the first alignment marks 1701s may be selected from the alignment errors of the plurality of first alignment marks measured during the first exposure process 1701. The number of at least one first alignment mark 1701s may be less than the number of the multiple first alignment marks 1701f.

The second mean value 1720 of at least one first alignment mark 1701s may include at least one of a first sub mean value of first alignment errors and a second sub mean value of second alignment errors.

The substrate treatment method may include operation S1630 in which a third mean value 1730 for the alignment error of each of multiple second alignment marks 1702f measured during a second exposure process 1702 is obtained.

The second exposure process 1702 may be the exposure process for the lower substrate. The lower substrate may include the multiple second alignment marks 1702f. The alignment error for each of the second alignment marks 1702f may include at least one of a first alignment error in the first horizontal direction (for example, X-axis direction) and a second alignment error in the second horizontal direction (for example, Y-axis direction).

The third mean value 1730 of the second alignment marks 1702f may include at least one of a first sub mean value of first alignment errors and a second sub mean value of second alignment errors.

The substrate treatment method may include operation S1640 in which a fourth mean value 1740 for the alignment error of at least one second alignment mark 1702s among the multiple second alignment marks 1702f is obtained.

At least one second alignment mark 1702s can be selected from the plurality of second alignment marks 1702f to obtain the fourth mean value 1740 of the subsampling method. The number of the at least one second alignment mark 1702s may be less than the number of the multiple second alignment marks 1702f. The number of the at least one first alignment mark 1701s and the number of at least one second alignment mark 1702s may be equal to each other. At least one of the first alignment mark 1701s and at least one of the second alignment mark 1702s may be alignment marks at positions that correspond to each other.

The fourth mean value 1740 of at least one second alignment mark 1702s may include at least one of a first sub mean value of a first alignment error and a second sub mean value of a second alignment error.

Meanwhile, the first exposure process 1701 and the second exposure process 1702 may be performed sequentially. In this case, the first exposure process 1701 may be performed first, and the second exposure process 1702 may be performed later. In another case, the second exposure process 1702 may be performed first, followed by the first exposure process 1701. In another example embodiment, the first exposure process 1701 and the second exposure process 1702 may be performed simultaneously.

The substrate treatment method may include operation S1650 in which a fifth mean value 1750 is obtained for the alignment error between at least one first alignment mark and at least one second alignment mark 1703s measured during bonding process 1703.

The alignment error for the at least one first alignment mark and at least one second alignment mark for 1703s may be measured during the bonding process 1703. The bonding process 1703 may be performed after the first exposure process 1701 and the second exposure process 1702. The at least one first alignment mark and at least one second alignment mark 1703s may be alignment marks at positions corresponding to at least one first alignment mark 1701s of the first exposure process 1701 and at least one second alignment mark 1702s of the second exposure process 1702.

The alignment error for the at least one first alignment mark and at least one second alignment mark 1703s may include at least one of a first alignment error in the first horizontal direction (for example, X-axis direction) and a second alignment error in the second horizontal direction (for example, Y-axis direction). The first alignment error may represent the difference in coordinates in the first horizontal direction (for example, X-axis direction) between the first alignment mark and the second alignment mark, and the second alignment error may represent the difference in coordinates in the second horizontal direction (for example, Y-axis direction) between the first alignment mark and the second alignment mark.

The fifth mean value 1750 of the at least one first alignment mark and at least one second alignment mark 1703s may include at least one of a first sub mean value of the first alignment error and a second sub mean value of the second alignment error.

The substrate treatment method may include operation S1660 in which offset 1760 is obtained by compensating the fifth mean value 1750 using the first difference value between the second mean value 1720 and the first mean value 1710, and using the second difference value between the fourth mean value 1740 and the third mean value 1730.

The first difference value may include either the first sub-difference value or the second sub-difference value. The first sub-difference value may be the first difference value for the first horizontal direction, and the second sub-difference value may be the first difference value for the second horizontal direction. The first sub-difference value may be the value obtained by subtracting the first sub mean value of the first mean value 1710 from the first sub mean value of the second mean value 1720, and the second sub-difference value may be the value obtained by subtracting the second sub mean value of the first mean value 1710 from the second sub mean value of the second mean value 1720.

The second difference value may include one of the third sub-difference value and the fourth sub-difference value. The third sub-difference value may be the second difference value for the first horizontal direction, and the fourth sub-difference value may be the first difference value for the second horizontal direction. The third sub-difference value may be the value obtained by subtracting the first sub mean value of the third mean value 1730 from the first sub mean value of the fourth mean value 1740, and the fourth sub-difference value may be the value obtained by subtracting the second sub mean value of the third mean value 1730 from the second sub mean value of the fourth mean value 1740.

The fifth mean value 1750 may include the first sub mean value and the second sub mean value. Here, the first sub mean value may be the fifth mean value 1750 for the first horizontal direction, and the second sub mean value may be the fifth mean value 1750 for the second horizontal direction. The offset 1760 may include a first offset and a second offset. Here, the first offset may be the offset 1760 in the first horizontal direction, and the second offset may be the offset 1760 in the second horizontal direction.

The first offset of the offset 1760 may be obtained by correcting the first sub mean value of the fifth mean value 1750 using the first sub-difference value and the third sub-difference value. For example, the first offset may be the value obtained by subtracting the difference value between the first sub-difference value and the third sub-difference value from the first sub mean value of the fifth mean value 1750. The second offset of the offset 1760 may be obtained by correcting the second sub mean value of the fifth mean value 1750 using the second sub-difference value and the fourth sub-difference value. For example, the second offset may be the value obtained by subtracting the difference value between the second sub-difference value and the fourth sub-difference value from the second sub mean value of the fifth mean value 1750.

In an example embodiment, the substrate treatment method may further include rotating the upper substrate about the second horizontal direction (for example, Y-axis direction) perpendicular to the first horizontal direction (for example, X-axis direction) in order for the upper surface of the upper substrate to face the upper surface of the lower substrate during the bonding process. Here, the upper substrate may be rotated 180 degrees about the second horizontal direction. In this case, the sign of the values associated with the upper substrate with respect to the first horizontal direction may be changed (e.g., reversed). For example, the sign of the first sub-difference value among the first difference values may change.

In an example embodiment, a delta value may be obtained for the first horizontal direction by adding the first difference value for the first horizontal direction and the second difference value for the first horizontal direction, and the offset for the first horizontal direction may be obtained by subtracting the delta value for the first horizontal direction from the fifth mean value for the first horizontal direction. The first difference value for the first horizontal direction may be the first sub-difference value, and the second difference value for the first horizontal direction may be the third sub-difference value. The fifth mean value for the first horizontal direction may be the first sub mean value included in the fifth mean value. The offset for the first horizontal direction may be the first offset.

In an example embodiment, a delta value for the second horizontal direction may be obtained by subtracting the second difference value for the second horizontal direction from the first difference value for the second horizontal direction, and the offset for the second horizontal direction may be obtained by subtracting the delta value for the second horizontal direction from the fifth mean value for the second horizontal direction. The first difference value for the second horizontal direction may be the second sub-difference value, and the second difference value for the second horizontal direction may be the fourth sub-difference value. The fifth mean value for the second horizontal direction may be the second sub mean value included in the fifth mean value. The offset for the second horizontal direction may be the second offset.

In an example embodiment, operation S1670 in which a position of the selected substrate is aligned may include performing a translational movement on the selected substrate in order for multiple alignment marks of the selected substrate to move in the opposite direction of the sign of the offset. For example, in the substrate treatment method, when the sign of the offset for the first horizontal direction (for example, first offset) is negative, the translational movement may be performed on the substrate in the positive first horizontal direction, and when the sign of the offset in the first horizontal direction is positive, the translational movement may be performed on the substrate in the negative first horizontal direction.

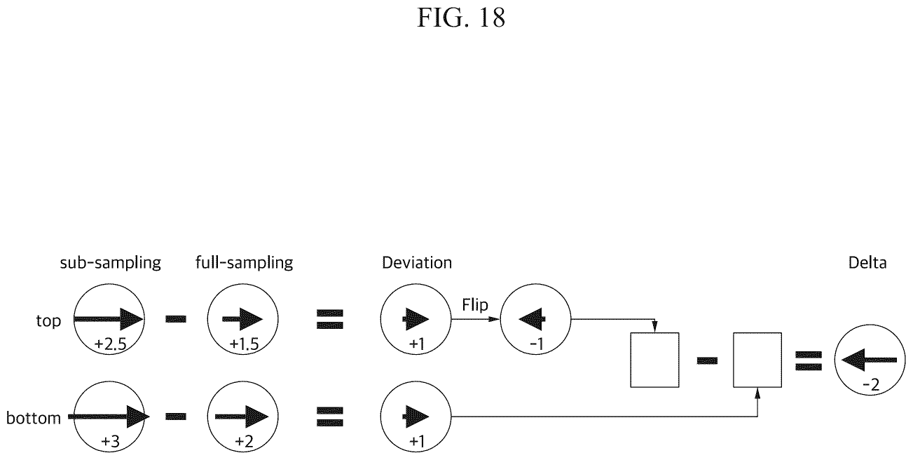

FIG. 18 is a diagram for explaining the process for obtaining a delta value according to an example embodiment.

Referring to FIG. 17 and FIG. 18, the upper substrate may be flipped along the second horizontal direction. Example embodiments are described assuming that a delta value for the first horizontal direction is obtained by using the alignment error for the first horizontal direction in the case regarding FIG. 17 and FIG. 18.

As shown in FIG. 18, for example, the first mean value 1710 for the alignment error of the multiple first alignment marks 1701f of the upper substrate may be +2.5, and the second mean value 1720 for the alignment error of at least one first alignment mark 1701s of the upper substrate may be +1.5. The first difference value of the second mean value 1720 and the first mean value 1710 is +1. As the upper substrate is flipped, the flipped first difference value is −1.

The third mean value 1730 for the alignment error of the multiple second alignment marks 1702f of the lower substrate may be +3, and the fourth mean value 1740 for the alignment error of the at least one second alignment mark 1702s of the lower substrate may be +2. The second difference value of the fourth mean value 1740 and the third mean value 1730 is +1.

The delta value may be the value obtained by subtracting the second difference value from the flipped first difference value. In this case, the delta value is −2. Meanwhile, when the substrate is not flipped or is not affected by the flip, the delta value may be the first difference value minus the second difference value.

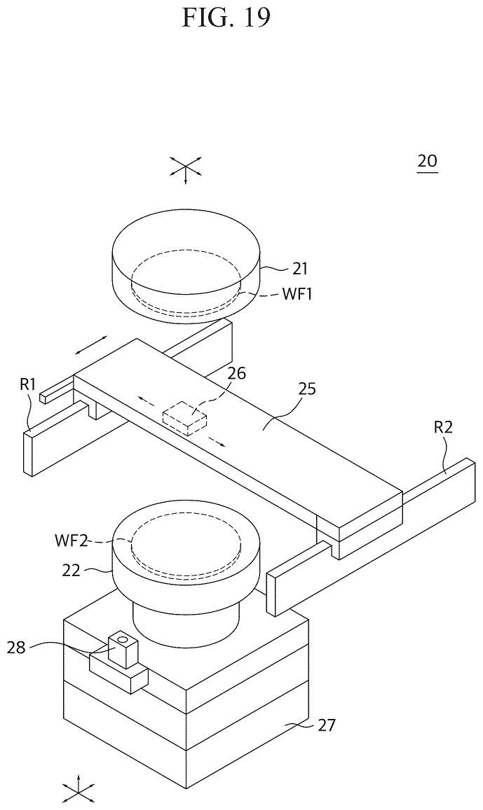

FIG. 19 is a drawing for explaining a bonding apparatus according to an example embodiment.

Referring to FIG. 19, the bonding apparatus 20 may be a device that performs the bonding process. The bonding apparatus 20 may align and bond the upper substrate WF1 to the lower substrate WF2.

According to an example embodiment, the bonding apparatus 20 may include the upper stage 21 and the lower stage 22. According to an example embodiment, the bonding apparatus 20 may include a sensor and a controller 27. According to an example embodiment, the bonding apparatus 20 may include a bonding head. The bonding head may be a device that applies laser, heat, and/or pressure to a substrate.

The upper stage 21 may support and fix the upper substrate WF1. The lower stage 22 may support and fix the lower substrate WF2. For example, the upper stage 21 and the lower stage 22 may use vacuum to fix the upper substrate WF1 and the lower substrate WF2. At least one of the upper stage 21 and the lower stage 22 may further include a driving part for adjusting the position thereof to align the upper substrate WF1 and the lower substrate WF2 with each other. The driving part may include, for example, one or more motors and/or one or more actuators.

In an example embodiment, in order for the upper substrate WF1 and the lower substrate WF2 to face each other, the upper stage 21 may be flipped while keeping the upper substrate WF1 fixed.

In an example embodiment, translational movement may be performed on at least one of the upper stage 21 and the lower stage 22 in the first horizontal direction and/or the second horizontal direction. In an example embodiment, at least one of the upper stage 21 and the lower stage 22 may rotate in either a clockwise or a counterclockwise direction. In an example embodiment, at least one of the upper stage 21 and the lower stage 22 may have a hole formed for bending a substrate selected between the upper substrate WF1 and the lower substrate WF2.

The sensor may measure second sampling alignment error data for at least one alignment mark. For example, the sensor may identify at least one alignment mark among the alignment marks included in the upper substrate WF1 when the upper substrate WF1 is loaded into the upper stage 21, and the sensor may identify at least one alignment mark among the alignment marks included in the lower substrate WF2 while the lower substrate WF2 is loaded into the lower stage 22. The sensor may measure an alignment error between at least one alignment mark of the upper substrate WF1 and at least one alignment mark of the lower substrate WF2.

In an example embodiment, the sensor may include a vision camera that photographs at least one of the upper substrate WF1 and the lower substrate WF2. The vision camera may include at least one of a mobile camera 26 and a fixed camera 28. In an example embodiment, the mobile camera 26 may be installed on a bridge 25 moving in the first horizontal direction along a first rail R1 and a second rail R2 which are spaced apart from each other. The mobile camera 26 may move in the first horizontal direction according to the movement of the bridge 25, and the mobile camera 26 may also move in the second horizontal direction within the bridge 25. The mobile camera 26 may identify the position of the alignment mark by photographing at least one of the upper substrate WF1 and the lower substrate WF2 while moving. The fixed camera 28 may be installed in a fixed location. The fixed camera 28 may identify the position of the alignment mark by photographing at least one of the upper substrate WF1 and the lower substrate WF2 at a fixed position.

The controller 27 may control the overall operation of the bonding apparatus 20. For example, the controller 27 may compute or process data. The controller 27 may output signals to control other components of the bonding apparatus 20. For example, the controller 27 may include at least one of a processor and a CPU.

The controller 27 may determine a third model of the upper substrate and the lower substrate using second sampling alignment error data for at least one alignment mark of each of the upper substrate and the lower substrate. The controller 27 may determine the fourth model by correcting the third model using the difference between the second model and the first model. The controller 27 may control a stage loading a selected substrate to align the position of the substrate selected between the upper substrate and the lower substrate according to the fourth model. The controller 27 may control the bonding head to bond the upper substrate to the lower substrate while the upper substrate and the lower substrate are aligned.

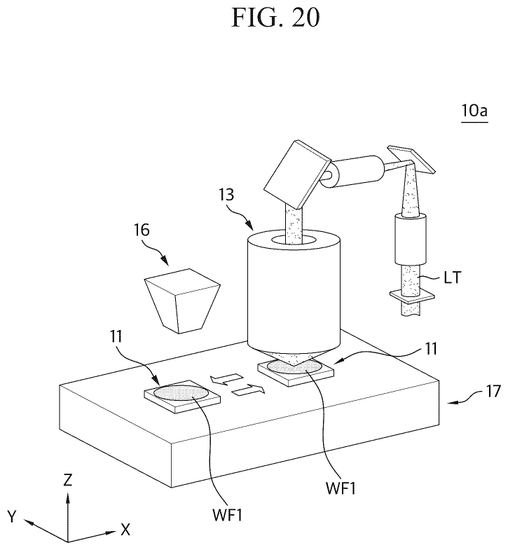

FIG. 20 is a drawing for explaining an exposure apparatus according to an example embodiment.

Referring to FIG. 20, the exposure apparatus 10a may include a stage 11, an exposure part 13, a sensor 16 and a controller 17.

On the stage 11, the upper substrate WF1 may be placed. In another example embodiment, a lower substrate WF2 may be placed on the stage 11. Below, example embodiments are explained based on the case where the upper substrate WF1 is placed. The stage 11 may support and fix the upper substrate WF1. The stage 11 may further include a driving part to align the upper substrate WF1 by adjusting its position.

The sensor 16 may measure alignment error data for multiple alignment marks. For example, the sensor 16 may identify each of multiple alignment marks included in the upper substrate WF1 when the upper substrate WF1 is loaded into the stage 11, and measure the alignment error between each alignment mark and the corresponding target point. Meanwhile, it is illustrated that the position of the sensor 16 is spaced from the exposure part 13 in the first horizontal direction (e.g., the X-direction). However, this is a mere example embodiment, and the sensor 16 may be positioned anywhere on the same XY coordinate plane. In this case, the sensor 16 may be located between the exposure part 13 and the upper substrate WF1.

An exposure part 13 may include a light source, an optical system, and a mask.

The light source may generate and output light LT. For example, the light LT may be extreme ultraviolet radiation having a wavelength greater than 5 nm and less than 50 nm, or ultraviolet radiation having a wavelength of 100 nm or more and less than 400 nm. However, this is a mere example embodiment, and the light LT may be transformed into light with various wavelengths when implemented. The light LT may be projected onto a substrate through an optical system and a mask.

The optical system may transmit the light LT that is output from a light source to a mask. For example, the optical system may include a lens and/or mirror that refracts or directs the light LT that is output from the light source. The optical system may include filters that transmit only certain wavelengths.

The mask may transmit light to certain areas and block light to other areas to form a circuit pattern. For example, the mask may include a substrate and a barrier film made of a material having transparent properties (for example, sapphire, quartz and so on). The barrier film may be a material such as chrome that blocks or absorbs light deposited in an area corresponding to the circuit pattern.

The controller 17 may control the overall operation of the exposure apparatus 10a. For example, the controller 17 may compute or process data. The controller 17 may output signals to control other components of the exposure apparatus 10a. For example, the controller 17 may include at least one of a processor and a CPU.

The controller 17 may measure alignment error data for multiple alignment marks of each of the upper substrate WF1 and the lower substrate via the sensor 16. The controller 17 may transmit alignment error data to either the APC 10b or the bonding apparatus 20. In an example embodiment, the controller 17 may obtain the first model using alignment error data for multiple alignment marks, and transmit the first model to either the APC 10b or the bonding apparatus 20.

In an example embodiment, the controller 17 may obtain first sampling alignment error data for at least one alignment mark from alignment error data for multiple alignment marks. The controller 17 may transmit first sampling alignment error data to either the APC 10b or the bonding apparatus 20. In an example embodiment, the controller 17 may obtain the second model using the first sampling alignment error data and transmit it to one of the APC 10b and the bonding apparatus 20.

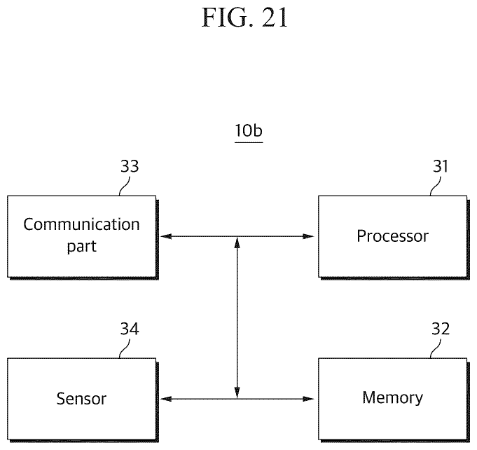

FIG. 21 is a drawing for explaining an APC according to an example embodiment.

Referring to FIG. 21, the APC 10b may include at least one of a processor 31, a memory 32, a communication part 33, and a sensor 34. The APC 10b may comprise a computer (e.g., formed by the processor 31 and memory 32). The APC 10b may be a device that manages at least one of the exposure apparatus 10a and the bonding apparatus 20. The communication part 33 may communicate data with at least one of the exposure apparatus 10a and the bonding apparatus 20.

The processor 31 may control the overall operation of the APC 10b. The processor 31 may perform an operation corresponding to a program by executing a program stored in the memory 32.

The processor 31 may receive alignment error data for multiple alignment marks of each of the upper substrate and the lower substrate from the exposure apparatus 10a via the communication part 33. The processor 31 may obtain the first model using alignment error data for multiple alignment marks. The processor 31 may transmit the first model to the bonding apparatus 20 via the communication part 33.

In an example embodiment, the processor 31 may obtain first sampling alignment error data for at least one alignment mark from alignment error data for multiple alignment marks. In another example embodiment, the processor 31 may obtain first sampling alignment error data for at least one alignment mark of each of the upper substrate and the lower substrate from the exposure apparatus 10a via the communication part 33. The processor 31 may obtain a second model using first sampling alignment error data for the obtained at least one alignment mark. The processor 31 may transmit the second model to the bonding apparatus 20 via the communication part 33. Meanwhile, the processor 31 may transmit the difference between the second model and the first model to the bonding apparatus 20 via the communication part 33.

The memory 32 may store various data. For example, the memory 32 may store programs executed by the processor 31. The memory 32 may store data processed by the processor 31. The memory 32 may store model or alignment error data transmitted or received via the communication part 33.

The sensor 34 may detect various types of information. The example embodiments are described assuming that a sensor for detecting alignment marks is provided in the exposure apparatus 10a or the bonding apparatus 20. However, when implemented, sensor may be equipped only in the APC 10b or may be additionally equipped in the APC 10b. For example, the sensor 34 may identify an alignment mark and measure alignment error data for the alignment mark.

The electronic device according to the above-described example embodiments may include a processor, a memory for storing and executing program data, a permanent storage such as a disk drive, and/or a user interface device such as a communication port, a touch panel, a key and/or a button that communicates with an external device. Methods implemented as software modules or algorithms may be stored in a computer-readable recording medium as computer-readable codes or program instructions executable on the processor. Here, the computer-readable recording medium includes a magnetic storage medium (for example, ROMs, RAMs, floppy disks and hard disks) and an optically readable medium (for example, CD-ROMs and DVDs). The computer-readable recording medium may be distributed among network-connected computer systems, so that the computer-readable codes may be stored and executed in a distributed manner. The medium may be readable by a computer, stored in a memory, and executed on a processer.

The example embodiments may be represented by functional block elements and various processing steps. The functional blocks may be implemented in any number of hardware and/or software configurations that perform specific functions. For example, an example embodiment may adopt integrated circuit configurations, such as memory, processing, logic and/or look-up table, that may execute various functions by the control of one or more microprocessors or other control devices. Disclosed operations may be performed by a processor, which is formed of hardware that may include a circuit. The processor may be configured by software programming. Further, the example embodiments may adopt the existing art for electronic environment setting, signal processing, and/or data processing. Terms such as “mechanism,” “element,” “means” and “configuration” may be used broadly and are not limited to mechanical and physical elements. The terms may include the meaning of a series of routines of software in association with a processor or the like.

The above-described example embodiments are merely examples, and other embodiments may be implemented within the scope of the disclosure.

What is claimed is:

1. A substrate treatment method comprising:
determining a first model of an upper substrate and a lower substrate based on alignment error data taken by measuring positions of a plurality of alignment marks of each of the upper substrate and the lower substrate;
determining a second model of the upper substrate and the lower substrate based on first sampling alignment error data regarding at least one alignment mark of the plurality of alignment marks, the first sampling alignment error data being selected from the alignment error data;
determining a third model of the upper substrate and the lower substrate based on second sampling alignment error data taken by measuring positions of the at least one alignment mark;
determining a fourth model by correcting the third model based on a difference between the second model and the first model; and
aligning a position of a substrate selected between the upper substrate and the lower substrate according to the fourth model.

2. The substrate treatment method of claim 1, wherein each of the first model, the second model, the third model and the fourth model comprises a first sub-model for modeling an alignment error in a first horizontal direction and a second sub-model for modeling an alignment error in a second horizontal direction.

3. The substrate treatment method of claim 2, wherein the first sub-model of each of the first model, the second model, the third model, and the fourth model comprises at least one alignment error component among a first offset component, a first scale component for a coordinate in the first horizontal direction and a first rotation component for a coordinate in the second horizontal direction, and
wherein the second sub-model of each of the first model, the second model, the third model, and the fourth model comprises at least one alignment error component among a second offset component, a second scale component for a coordinate in the second horizontal direction and a second rotation component for a coordinate in the first horizontal direction.

4. The substrate treatment method of claim 3, wherein the first scale component comprises an nth degree polynomial for the coordinate in the first horizontal direction, wherein n is an integer equal to or greater than 1, and
wherein the second scale component comprises an mth degree polynomial for the coordinate in the second horizontal direction, wherein m is an integer equal to or greater than 1.

5. The substrate treatment method of claim 3, wherein the aligning the position of the substrate comprises:
when the fourth model comprises an offset component, performing a translational movement of the selected substrate;
when the fourth model comprises a scale component, bending the selected substrate in a vertical direction; and
when the fourth model comprises a rotation component, rotating the selected substrate.

6. The substrate treatment method of claim 3, wherein a coefficient of the at least one alignment error component included in the first sub-model is determined based on a regression analysis, wherein the coordinate in the first horizontal direction and the coordinate in the second horizontal direction for each of the plurality of alignment marks are set as independent variables, and wherein the alignment error in the first horizontal direction for each of the plurality of alignment marks is set as a dependent variable, and
wherein a coefficient of the at least one alignment error component included in the second sub-model is determined based on a regression analysis, wherein the coordinate in the first horizontal direction and the coordinate in the second horizontal direction for each of the plurality of alignment marks are set as independent variables, and wherein the alignment error in the second horizontal direction for each of the plurality of alignment marks is set as a dependent variable.

7. The substrate treatment method of claim 2, wherein the first model comprises a first upper model for the upper substrate and a first lower model for the lower substrate, and the second model comprises a second upper model for the upper substrate and a second lower model for the lower substrate, and
wherein the determining the fourth model by correcting the third model based on the difference between the second model and the first model incudes:
obtaining a first upper difference between a first sub-model of the second upper model and a first sub-model of the first upper model;
obtaining a first lower difference between a first sub-model of the second lower model and a first sub-model of the first lower model;
obtaining a first delta model based on a difference between the first upper difference and the first lower difference; and
obtaining a first sub-model of the fourth model based on a difference between the first sub-model of the third model and the first delta model.

8. The substrate treatment method of claim 1, wherein a number of the at least one alignment mark is smaller than a number of the plurality of alignment marks.

9. The substrate treatment method of claim 8, wherein the at least one alignment mark comprises an alignment mark positioned at a center area of each of the upper substrate and the lower substrate.

10. The substrate treatment method of claim 1, wherein the first model is determined based on the alignment error data measured during a first process performed on the substrate, and
wherein the third model is determined based on the second sampling alignment error data measured during a second process performed on the substrate after the first process.

11. The substrate treatment method of claim 10, wherein the first process is an exposure process and the second process is a bonding process.

12. The substrate treatment method of claim 10, further comprising, after the position of the selected substrate is aligned, bonding the upper substrate to the lower substrate.

13. A substrate treatment method comprising:
obtaining a first mean value for an alignment error of each of a plurality of first alignment marks measured during a first exposure process performed on an upper substrate comprising the plurality of first alignment marks;
obtaining a second mean value for an alignment error of at least one first alignment mark among the plurality of first alignment marks;
obtaining a third mean value for an alignment error of each of a plurality of second alignment marks measured during a second exposure process performed on a lower substrate comprising the plurality of second alignment marks;
obtaining a fourth mean value for an alignment error of at least one second alignment mark among the plurality of second alignment marks;
obtaining a fifth mean value for an alignment error between the at least one first alignment mark and the at least one second alignment mark measured during a bonding process of the upper substrate to the lower substrate;
obtaining an offset by correcting the fifth mean value based on a first difference value between the second mean value and the first mean value, and a second difference value between the fourth mean value and the third mean value; and
aligning a position of a substrate selected between the upper substrate and the lower substrate according to the offset.

14. The substrate treatment method of claim 13, further comprising
rotating the upper substrate about an axis extending in a second horizontal direction perpendicular to a first horizontal direction, with an upper surface of the upper substrate facing an upper surface of the lower substrate during the bonding process after the rotation.

15. The substrate treatment method of claim 14,
wherein the alignment error of each of the plurality of first alignment marks and the plurality of second alignment marks includes a first alignment error in the first horizontal direction,
wherein the first mean value, the second mean value, the third mean value, the fourth mean value, and the fifth mean value each include a first sub mean value of first alignment errors in the first horizontal direction,
wherein the first difference value includes a first sub difference value between the first sub mean value of the second mean value and the first sub mean value of the first mean value,
wherein the second difference value includes a second sub difference value between the first sub mean value of the fourth mean value and the first sub mean value of the third mean value, and
wherein the obtaining the offset comprises:
obtaining a delta value for the first horizontal direction by summing the first sub difference value for the first horizontal direction and the second sub difference value for the first horizontal direction; and
obtaining an offset for the first horizontal direction by subtracting the first sub mean value of the fifth mean value for the first horizontal direction from the delta value for the first horizontal direction.

16. The substrate treatment method of claim 13, wherein the aligning the position of the selected substrate comprises performing a translational movement on the selected substrate in order for the plurality of alignment marks of the selected substrate to move in an opposite direction of a sign of the offset.

17. A substrate treatment system comprising:
an electronic apparatus including a processor configured to:
determine a first model of an upper substrate and a lower substrate based on alignment error data regarding a plurality of alignment marks of each of the upper substrate and the lower substrate; and
determine a second model of the upper substrate and the lower substrate based on first sampling alignment error data regarding at least one alignment mark from the alignment error data; and
a bonding apparatus configured to:
determine a third model of the upper substrate and the lower substrate based on second sampling alignment error data taken by measuring positions of the at least one alignment mark;
determine a fourth model by correcting the third model based on a difference between the second model and the first model received from the electronic apparatus; and
align a position of a substrate selected between the upper substrate and the lower substrate according to the fourth model.

18. The substrate treatment system of claim 17, wherein the electronic apparatus comprises an auto process control (APC) configured to receive the alignment error data from an exposure apparatus.

19. The substrate treatment system of claim 17, wherein the electronic apparatus comprises an exposure apparatus configured to measure the alignment error data.

20. The substrate treatment system of claim 17, wherein each of the first model, the second model, the third model and the fourth model comprises a first sub-model for modeling an alignment error in a first horizontal direction and a second sub-model for modeling an alignment error in a second horizontal direction,
wherein the first sub-model of each of the first model, the second model, the third model, and the fourth model comprises at least one alignment error component among a first offset component, a first scale component for a coordinate in the first horizontal direction and a first rotation component for a coordinate in the second horizontal direction, and
wherein the second sub-model of each of the first model, the second model, the third model, and the fourth model comprises at least one alignment error component among a second offset component, a second scale component for a coordinate in the second horizontal direction and a second rotation component for a coordinate in the first horizontal direction.
